(19) United States
(12) Patent Application Publication
(10) Pub. No.: US 2026/0026379 A1
(43) Pub. Date: Jan. 22, 2026

(54) SEMICONDUCTOR STRUCTURE AND FABRICATION METHOD THEREOF

(71) Applicant: Yangtze Memory Technologies Holding Co., Ltd., Wuhan (CN)

(72) Inventors: Shuyang Shen, Wuhan (CN); Min Wen, Wuhan (CN); Liang Xiao, Wuhan (CN); Wenbin Zhou, Wuhan (CN); Zongliang Huo, Wuhan (CN)

(73) Assignee: Yangtze Memory Technologies Holding Co., Ltd., Wuhan (CN)

(21) Appl. No.: 18/935,255

(22) Filed: Nov. 1, 2024

(30) Foreign Application Priority Data
Jul. 22, 2024 (CN) 202410986567.4

(51) Int. Cl. H01L 23/538; H01L 21/768; H01L 23/00; H01L 25/18; H10B 12/00; H10B 80/00

(52) U.S. Cl. CPC H01L 23/5386; H01L 21/76802; H01L 23/5384; H01L 24/05; H01L 24/08; H01L 24/16; H01L 24/80; H10B 12/50; H01L 25/18; H01L 2224/05556; H01L 2224/08145; H01L 2224/16227; H01L 2224/80895; H01L 2224/80896; H01L 2924/14361; H10B 80/00

(57) ABSTRACT

According to one aspect of the present disclosure, a semiconductor structure is provided. The semiconductor structure may include a first semiconductor chip and a second semiconductor chip that are bonded along a first direction. The first semiconductor chip may include a first semiconductor layer. The first semiconductor chip may include a plurality of first connection structures extending through the first semiconductor layer along the first direction. A dielectric material may be between and in contact with any two of the first connection structures. The first semiconductor chip and the second semiconductor chip may be coupled by a plurality of first bonding contacts and the plurality of first connection structures. The plurality of first bonding contacts may extend through a first dielectric layer. The first connection structure may be coupled with the first bonding contact.

### CROSS-REFERENCE TO RELATED APPLICATIONS

The present application claims the benefit of priority to Chinese Application No. 202410986567.4, filed on Jul. 22, 2024, which is hereby incorporated by reference in its entirety.

### TECHNICAL FIELD

Examples of the present disclosure relate to the field of semiconductor technology, and particularly to a semiconductor structure and a fabrication method thereof.

### BACKGROUND

A three-dimensional integrated circuit may be formed by stacking semiconductor chips that have electronic circuitries formed therein or thereon. These stacked semiconductor chips may be vertically interconnected. The stacked semiconductor chips may be interconnected using through silicon vias (TSVs) to form a circuit structure with electrical functions. For example, multiple memory chips may be stacked and interconnected using through silicon vias to obtain a high-bandwidth memory (HBM), which shortens interconnection length between the chips and improves performance of a memory product. With the increasing of integration level of the semiconductor chips, the integration level of the through silicon vias becomes increasingly higher, and there is much room for the improvement of the chip stacking process.

### SUMMARY

According to one aspect of the present disclosure, a semiconductor structure is provided. The semiconductor structure may include a first semiconductor chip and a second semiconductor chip that are bonded along a first direction. The first semiconductor chip may include a first semiconductor layer. The first semiconductor chip may include a plurality of first connection structures extending through the first semiconductor layer along the first direction. A dielectric material may be between and in contact with any two of the first connection structures. The first semiconductor chip and the second semiconductor chip may be coupled by a plurality of first bonding contacts and the plurality of first connection structures. The plurality of first bonding contacts may extend through a first dielectric layer. The first connection structure may be coupled with the first bonding contact.

In some implementations, the first semiconductor chip may include a first isolation structure extending through the first semiconductor layer along the first direction and including the dielectric material. In some implementations, the plurality of first connection structures may extend through the first isolation structure along the first direction.

In some implementations, a size in a second direction of an end of the first connection structure close to the second semiconductor chip along the first direction may be greater than or equal to a size in the second direction of an end of the first connection structure away from the second semiconductor chip. In some implementations, the second direction may intersect the first direction.

In some implementations, the first semiconductor chip may include a first semiconductor sub-structure and a second semiconductor sub-structure that are bonded along the first direction. In some implementations, the first semiconductor layer may be located in the first semiconductor sub-structure and located between the second semiconductor sub-structure and the second semiconductor chip. In some implementations, the first semiconductor sub-structure and the second semiconductor sub-structure may be coupled by a plurality of second bonding contacts extending through a second dielectric layer. In some implementations, the first connection structure may include a first connection sub-structure in the first semiconductor sub-structure and a second connection sub-structure in the second semiconductor sub-structure. In some implementations, the second bonding contacts may be located between the first connection sub-structure and the second connection sub-structure. In some implementations, the first connection sub-structure and the second connection sub-structure may be coupled by the second bonding contacts.

In some implementations, the second semiconductor chip may include a third semiconductor sub-structure and a fourth semiconductor sub-structure that are bonded in the first direction. In some implementations, the fourth semiconductor sub-structure may be located between the first semiconductor chip and the third semiconductor sub-structure. In some implementations, the fourth semiconductor sub-structure and the third semiconductor sub-structure may be coupled by a plurality of third bonding contacts extending through a third dielectric layer. In some implementations, the third dielectric layer and the first dielectric layer may be located on two sides of the fourth semiconductor sub-structure that are opposite in the first direction.

In some implementations, the second semiconductor chip may further include a second connection structure extending along the first direction. In some implementations, the second connection structure may be located between the first bonding contact and the third bonding contact. In some implementations, the second connection structure may be coupled with the first bonding contact and the third bonding contact.

In some implementations, the second connection structure may include a third connection sub-structure in the third semiconductor sub-structure and a fourth connection sub-structure in the fourth semiconductor sub-structure. In some implementations, the third bonding contact may be located between the third connection sub-structure and the fourth connection sub-structure. In some implementations, the third connection sub-structure and the fourth connection sub-structure may be coupled by the third bonding contact.

In some implementations, the third semiconductor sub-structure may further include a second semiconductor layer and a second isolation structure extending through the second semiconductor layer along the first direction. In some implementations, a plurality of the third connection sub-structures may extend through the second isolation structure.

In some implementations, the second semiconductor sub-structure may include a transistor including a first active region, a second active region, and a gate layer. In some implementations, the second semiconductor sub-structure may include a bit line coupled with the first active region. In some implementations, the second semiconductor sub-structure may include a capacitor structure coupled with the second active region.

In some implementations the transistor may include a semiconductor pillar extending along the first direction. In some implementations, the first active region and the second active region may be located at two ends of the semiconductor pillar that are opposite in the first direction. In some implementations, the gate layer may extend along a direction intersecting the first direction. In some implementations, the gate layer may cover part of a side of the semiconductor pillar.

In some implementations, the first semiconductor sub-structure may include a peripheral circuit coupled with the bit line by part of the second bonding contacts and coupled with the gate layer by another part of the second bonding contacts.

In some implementations, the semiconductor structure may include a third semiconductor chip located on a side of the first semiconductor chip away from the second semiconductor chip. In some implementations, the third semiconductor chip may include a control logic circuit and may be bonded with the first semiconductor chip, and the first connection structure is coupled with the third semiconductor chip.

In some implementations, the semiconductor structure may include an intermediary substrate located on a side of the third semiconductor chip away from the first semiconductor chip. In some implementations, the third semiconductor chip may be coupled with the intermediary substrate.

According to another aspect of the present disclosure, a semiconductor structure is provided. The semiconductor structure may include a first semiconductor sub-structure and a second semiconductor sub-structure that are bonded in a first direction. The first semiconductor sub-structure may include a first semiconductor layer. The first semiconductor sub-structure may include a plurality of first connection sub-structures extending through the first semiconductor layer along the first direction. A dielectric material may be between and in contact with any two of the first connection sub-structures. The semiconductor structure may include a pad that is located on a side of the first semiconductor sub-structure away from the second semiconductor sub-structure and may be coupled with the first connection sub-structure.

In some implementations, the first semiconductor sub-structure may include a first isolation structure extending through the first semiconductor layer along the first direction and including the dielectric material. In some implementations, the plurality of first connection sub-structures may extend through the first isolation structure along the first direction.

In some implementations, the first semiconductor sub-structure and the second semiconductor sub-structure may be coupled by a plurality of bonding contacts and the first connection sub-structures. In some implementations, the plurality of bonding contacts may extend through a dielectric layer. In some implementations, the first connection sub-structure may be coupled with the bonding contact.

In some implementations, the second semiconductor sub-structure may include a second connection sub-structure extending along the first direction. In some implementations, the bonding contacts may be located between the first connection sub-structure and the second connection sub-structure. In some implementations, the first connection sub-structure and the second connection sub-structure may be coupled by the bonding contacts.

In some implementations, a size in a second direction of an end of the first connection sub-structure away from the second semiconductor sub-structure along the first direction may be greater than or equal to a size in the second direction of an end of the first connection sub-structure close to the second semiconductor sub-structure. In some implementations, the second direction may intersect the first direction.

In some implementations, the second semiconductor sub-structure may include a transistor including a first active region, a second active region, and a gate layer. In some implementations, the second semiconductor sub-structure may include a bit line coupled with the first active region. In some implementations, the second semiconductor sub-structure may include a capacitor structure coupled with the second active region.

In some implementations, the transistor may include a semiconductor pillar extending along the first direction. In some implementations, the first active region and the second active region may be located at two ends of the semiconductor pillar that are opposite in the first direction. In some implementations, the gate layer may extend along a direction intersecting the first direction, and covers part of a side of the semiconductor pillar.

In some implementations, the second semiconductor sub-structure may include a peripheral circuit coupled with the bit line by part of the bonding contacts and coupled with the gate layer by another part of the bonding contacts.

In some implementations, a composition material of the dielectric layer may include carbon-doped silicon nitride.

In some implementations, a composition material of the pad may include at least one of aluminum, copper, nickel, titanium, tungsten, gold, silver and platinum.

According to a further aspect of the present disclosure, a method of fabricating a semiconductor structure is provided. The method may include etching a first semiconductor layer of a first semiconductor sub-structure to form a groove extending through the first semiconductor layer. The method may include filling a dielectric material in the groove to form a first isolation structure. The method may include forming a plurality of openings extending through the first isolation structure. The method may include forming first connection sub-structures in the openings.

In some implementations, the first semiconductor sub-structure may include a device structure on the first semiconductor layer. In some implementations, the method may further include etching a side of the first semiconductor layer away from the device structure to form the groove. In some implementations, the groove may expose at least part of the device structure, and the first connection sub-structure may be coupled with at least part of the device structure.

In some implementations, the openings may extend along a first direction, and a size of an open end of the opening in a second direction may be greater than or equal to a size of a bottom of the opening in the second direction. In some implementations, the second direction may intersect the first direction.

In some implementations, the method may include forming a pad on the first connection sub-structure. In some implementations, the pad may be located on a side of the first semiconductor layer away from the device structure and may be coupled with the first connection sub-structure.

In some implementations, the forming the first isolation structure may include filling a dielectric material in the groove. In some implementations, the forming the first isolation structure may include planarizing an exposed surface of the dielectric material to form the first isolation structure. In some implementations, a surface of the first isolation structure may be flush with a surface of the first semiconductor layer.

In some implementations, the method may include bonding the first semiconductor sub-structure with a second semiconductor sub-structure. In some implementations, the first connection sub-structure may be coupled with a bonding contact. In some implementations, the first semiconductor sub-structure may include a peripheral circuit. In some implementations, the second semiconductor sub-structure may include a transistor and a capacitor structure coupled with the transistor. In some implementations, the first semiconductor sub-structure and the second semiconductor sub-structure may be coupled by the bonding contact and the first connection sub-structure.

In some implementations, the method may include forming a second connection sub-structure in the second semiconductor sub-structure. In some implementations, the second connection sub-structure may be coupled with the bonding contact.

### BRIEF DESCRIPTION OF THE DRAWINGS

FIGS. 1 to 8 are schematic diagrams of an example semiconductor structure according to examples of the present disclosure;

FIGS. 9 to 11 are other schematic diagrams of an example semiconductor structure according to examples of the present disclosure;

FIGS. 12a to 12d are schematic diagrams of a fabrication method of a semiconductor structure according to examples of the present disclosure;

FIG. 13 is a flow diagram of an example fabrication method of a semiconductor structure according to examples of the present disclosure;

FIGS. 14a to 14f are schematic diagrams I of a fabrication method of a semiconductor structure according to examples of the present disclosure;

FIG. 15 is a schematic diagram II of a fabrication method of a semiconductor structure according to examples of the present disclosure;

FIGS. 16 and 17 are schematic diagrams of an example system according to examples of the present disclosure; and

FIGS. 18 and 19 are schematic diagrams of an example package structure according to examples of the present disclosure.

### DETAILED DESCRIPTION

Example implementations disclosed in the present disclosure will be described in more detail with reference to the drawings. Although the example implementations of the present disclosure are shown in the drawings, it is to be understood that the present disclosure may be implemented in various forms and should not be limited by the specific implementations set forth herein. Rather, these implementations are provided for a more thorough understanding of the present disclosure, and to fully convey a scope disclosed by the present disclosure to those skilled in the art.

In the following description, numerous specific details are given in order to provide a more thorough understanding of the present disclosure. However, it is apparent to those skilled in the art that the present disclosure may be implemented without one or more of these details. In other examples, in order to avoid confusion with the present disclosure, some technical features well-known in the art are not described; that is, not all features of actual examples are described here, and well-known functions and structures are not described in detail.

It is to be understood that when an element or a layer is referred to as being “on”, “adjacent to”, “connected to”, or “coupled to” other elements or layers, it may be directly on, adjacent to, connected to, or coupled to the other elements or layers, or intervening elements or layers may be present. In contrast, when an element is referred to as being “directly on”, “immediately adjacent to”, “directly connected to”, or “directly coupled to” other elements or layers, no intervening elements or layers are present. It is to be understood that, although the terms first, second, third, etc. may be used to describe various elements, components, areas, layers, and/or portions, these elements, components, areas, layers, and/or portions should not be limited by these terms. These terms are only used to distinguish one element, component, area, layer or portion from another element, component, area, layer or portion. Thus, a first element, component, area, layer or portion discussed below may be denoted as a second element, component, area, layer or portion, without departing from the teachings of the present disclosure. When the second element, component, area, layer or portion is discussed, it does not mean that the first element, component, area, layer or portion is necessarily present in the present disclosure.

The spatially relative terms, such as “beneath”, “below”, “lower”, “under”, “over”, “upper”, and the like, may be used herein for ease of description to describe one element or feature's relationship to another element or feature as illustrated in the figures. It should be understood that in addition to orientations shown in the figures, the spatial relationship terms are intended to further include the different orientations of a structure in use and operation. For example, if a structure in the drawings is turned over, then an element or a feature described as being “below”, “under”, or “beneath” another element or feature will be orientated as being “on” another element or feature. Therefore, the example terms “below” and “beneath” may comprise both upper and lower orientations. The structure may be orientated otherwise (rotated by 90 degrees or in other orientations), and the spatially descriptive terms used herein are interpreted accordingly.

The terms used herein are only intended to describe the specific examples, and are not used as limitations of the present disclosure. As used herein, unless otherwise indicated expressly in the context, “a”, “an” and “the” in a singular form are also intended to comprise a plural form. It should also be understood that terms “consist of” and/or “comprise”, when used in this specification, determine the presence of the described features, integers, steps, operations, elements and/or components, but do not preclude the presence or addition of one or more of other features, integers, steps, operations, elements, components, and/or groups. As used herein, the term “and/or” comprises any or all combinations of the listed relevant items.

It is to be understood that references to “some examples” or “an example” throughout this specification mean that particular features, structures, or characteristics related to the example(s) are comprised in at least one example of the present disclosure. Therefore, “in some examples” or “in an example” presented throughout this specification does not necessarily refer to the same example. In addition, these specific features, structures or characteristics may be combined in one or more examples in any suitable manner. It is to be understood that, in various examples of the present disclosure, sequence numbers of the above processes do not indicate an execution sequence, and an execution sequence of the processes shall be determined by functionalities and intrinsic logics thereof, and shall constitute no limitation on an implementation process of examples of the present disclosure.

With the recent rapid development and extensive expansion of artificial intelligence, machine learning, high-performance computing, graphics, automotive and network applications, there is a growing demand for a variety of integrated circuits with high performance, large computing power or high storage density. The planar integration of integrated circuits occupies more area, while three-dimensional integration of the integrated circuits can achieve increased integration density. A semiconductor structure is provided according to examples of the present disclosure. The semiconductor structure includes a structure of a plurality of semiconductor chips stacked and bonded in a thickness direction or a vertical direction to endow the semiconductor structure with more electrical functions and higher integration density and reduce a horizontal footprint. The semiconductor chip in the examples of the present disclosure may refer to a semiconductor wafer, including, but not limited to, a silicon-based chip, a germanium-based chip, a silicon carbide chip, and other semiconductor chips fabricated based on a semiconductor wafer and having electrical, optical, acoustic, and other functions. The semiconductor chip or semiconductor structure may be a structure cut from the semiconductor wafer, and the semiconductor chip may have an electronic circuitry formed therein or thereon. The semiconductor chip may include coupling of a plurality of semiconductor sub-structures, including two-dimensional integrated coupling in a horizontal direction, or including three-dimensional bonding coupling in a vertical direction. Examples of the semiconductor chip include a memory logic chip, a memory core chip, a central processing unit chip, and other electronic device chips.

The examples of the semiconductor structure, the semiconductor chip, and the semiconductor sub-structure described above in the examples of the present disclosure are merely schematic, and are merely illustrative of a hierarchical logical division of an inclusion relationship for the convenience of explanation, and there may be other division methods in actual implementation, to which the present disclosure has no limitations. In some other examples, for example, a plurality of structures, chips, units or assemblies may be combined or may be integrated to another system, or some features may be omitted or not be included.

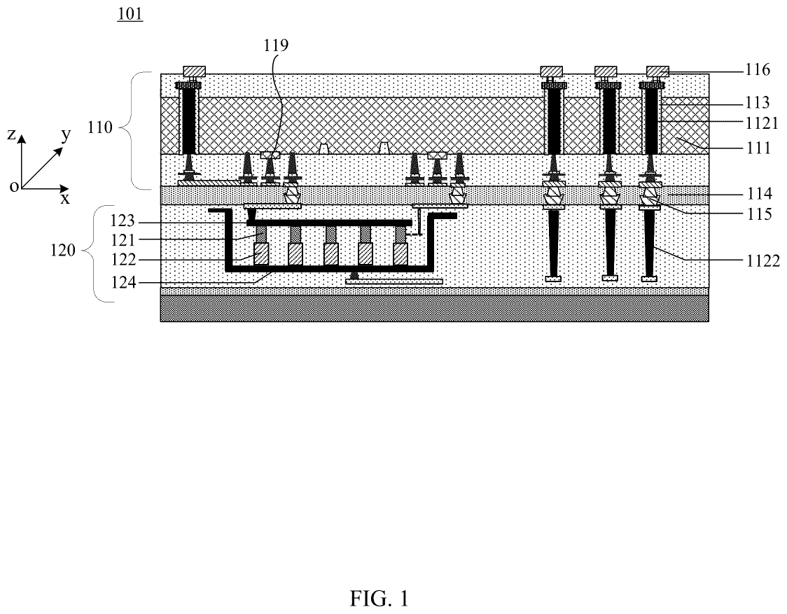

According to some aspects of examples of the present disclosure, FIG. 1 provides a semiconductor structure 101 or a semiconductor chip 101, which may include a first semiconductor sub-structure 110 and a second semiconductor sub-structure 120 that are bonded in a first direction. The first direction may be a z-direction, a vertical direction or a thickness direction. The first semiconductor sub-structure 110 may include: a first semiconductor layer 111 that may be a semiconductor substrate or a thinned semiconductor substrate, or a film layer deposited on a substrate; a first connection sub-structure 1121 extending through the first semiconductor layer 111 along the z-direction; and an isolation layer 113 between the first connection sub-structure 1121 and the first semiconductor layer 111. The insulating layer 113 surrounds a sidewall of the first connection sub-structure 1121 to electrically isolate the first semiconductor layer 111 to reduce electrical leakage and interference. The second semiconductor sub-structure 120 and the first semiconductor sub-structure 110 may be coupled by a plurality of bonding contacts 115 extending through a dielectric layer 114 and the first connection sub-structure 1121 coupled with the bonding contacts 115, so as to achieve electrical signal interconnection of the two semiconductor sub-structures. The bonding may include hybrid bonding, and the electrical signal interconnection may include, but is not limited to, power supply, control signal interaction, data transmission, etc.

In some examples, before the two semiconductor sub-structures 101 are bonded, surfaces to be bonded of the first semiconductor sub-structure 110 and the second semiconductor sub-structure 120 have a first bonding sub-layer with a plurality of first bonding sub-contacts and a second bonding sub-layer with a plurality of second bonding sub-contacts, respectively. The first bonding sub-contacts extend through a first dielectric sub-layer, and the second bonding sub-contacts extend through a second dielectric sub-layer. The first bonding sub-contacts and the second bonding sub-contacts lead out electrical signals of the semiconductor sub-structures to the surfaces to be bonded, respectively. The bonding sub-contact may include a pad 116, a conductive plug and other structures. The surfaces to be bonded or sub-layers to be bonded of the first semiconductor sub-structure 110 and the second semiconductor sub-structure 120 are bonded, and surfaces of the two sub-layers to be bonded are in contact to form a bonding interface. The first dielectric sub-layer and the second dielectric sub-layer are in contact and bonded at the bonding interface to achieve bonding and fixing of the first semiconductor sub-structure 110 and the second semiconductor sub-structure 120. A larger bonding area provides a larger bonding force. When composition materials of the first dielectric sub-layer and the second dielectric sub-layer are the same or similar, they may have no physical boundary, which may be considered as the dielectric layer 114 in FIG. 1. Part of the dielectric layer 114 in the first semiconductor sub-structure 110 may be considered as the first dielectric sub-layer, and part of the dielectric layer 114 in the second semiconductor sub-structure 120 may be considered as the second dielectric sub-layer. The bonding sub-contact and the second bonding sub-contact are in contact and bonded at the bonding interface to achieve electrical signal interconnection between the first semiconductor sub-structure 110 and the second semiconductor sub-structure 120. There may be no physical boundary after the first bonding sub-contact is bonded with the second bonding sub-contact, and they may be considered as the bonding contact 115 in the figure. The bonding contact 115 extends through the dielectric layer 114. The part of the bonding contact 115 in the first semiconductor sub-structure 110 is the first bonding sub-contact before bonding, and the part of the bonding contact 115 in the second semiconductor sub-structure 120 is the second bonding sub-contact before bonding.

In an example, the first connection sub-structure 1121 may be a conductive plug, a conductive pillar, a conductive strip or a TSV, etc. extending along the z-direction. The shape of the first connection sub-structure 1121 may include a cylinder, a polyhedron or other shapes. A composition material of the first connection structure 112 may include, but is not limited to, conductive materials such as aluminum, copper, nickel, titanium, tungsten, gold, silver and platinum, etc. A composition material of the first semiconductor layer 111 may include any semiconductor material in the art, including, but not limited to, an elemental semiconductor material (e.g., silicon and germanium), a group III-V compound semiconductor material, group II-VI compound semiconductor materials, an organic semiconductor material or other semiconductor materials known in the art, for example, monocrystalline silicon, polysilicon, germanium, silicon carbide or indium gallium zinc oxide (IGZO) or other materials.

In some examples, with reference to FIG. 1, the second semiconductor sub-structure 120 further includes a second connection sub-structure 1122 coupled with the bonding contact 115, and an electrical signal of the second semiconductor sub-structure 120 is led out by the second connection sub-structure 1122 and is interconnected with the electrical signal of the first semiconductor sub-structure 110 through the bonding contact 115 and the first connection sub-structure 1121. The second connection sub-structure 1122 may include, but is not limited to, a conductive plug, a conductive pillar or a conductive strip and other structures. The second connection sub-structure 1122 may include a plurality of conductive structures stacked along the z-direction.

In some examples, with reference to FIG. 1, the semiconductor structure 101 further includes a pad 116 on a side of the first semiconductor sub-structure 110 away from the second semiconductor sub-structure 120. The pad 116 is coupled with the first connection sub-structure 1121, and may serve as a bonding pad to be coupled with other semiconductor structures 101, or serve as an IO interface for power supply or data transmission.

In some examples, the semiconductor structure 101 may include memory cells constituting a memory device, including but not limited to DRAM, NAND, and SRAM memory devices. The semiconductor structure 101 in FIG. 1 may be a DRAM as an example. The semiconductor structure 101 in FIG. 1 may be a DRAM, or at least part of a memory device in the DRAM, and may be applicable to a double-data-rate synchronous dynamic random access memory using a DDR4 memory specification and a DDR5 memory specification, and a low-power double-data-rate synchronous dynamic random access memory using a LPDDR5 memory specification.

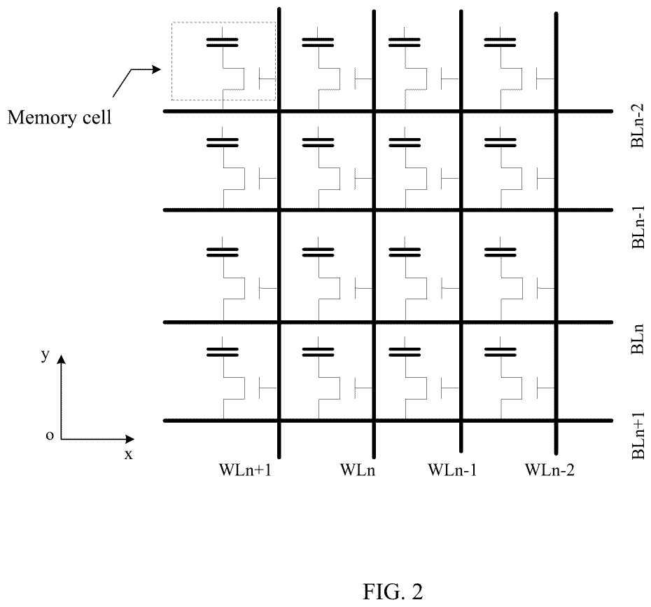

In the DRAM, a memory array may be arranged in rows and columns, such that the memory cell may be addressed by specifying a row and a column of its array. The memory array includes a plurality of word lines and a plurality of bit lines, and the word lines intersect the bit lines. A memory cell at an intersection of a selected word line and a selected bit line is selected to perform a read, write or refresh operation. As illustrated in FIG. 2, the memory array may include a plurality of word lines WLn, WLn+1, WLn−1 and WLn−2, and a plurality of bit lines 123 BLn, BLn+1, BLn−1 and BLn−2. The word lines intersect the bit lines. The memory cell in the memory array may include a capacitor and a transistor, and one memory cell may include one transistor and one capacitor. The word line may be also a conductive structure like a gate layer, etc., which serves as a gate of the transistor. One controlled terminal (source) of the transistor is coupled with one electrode of the capacitor, the other controlled terminal (drain) of the transistor is coupled with the bit line, and the other electrode of the capacitor may be grounded or applied with other voltages (e.g., vdd/2). As shown in FIG. 2, the memory cell array is arranged in x rows and y columns. The rows may be perpendicular or not perpendicular to the columns, the x-direction may be labeled as a second direction, and the y-direction may be labeled as a third direction. An extending direction of the bit line 123 may be parallel to the x-direction or have an included angle with the x-direction. An extending direction of the word line may be parallel to the y-direction or have an included angle with the y-direction. An orthographic projection of the word line on the xoy plane and an orthographic projection of the bit line on the xoy plane are perpendicular, or are not perpendicular but have a certain included angle, to which the examples of the present disclosure have no limitations. The z-direction in examples below may be the first direction, and may be perpendicular to the xoy plane or intersect but be not perpendicular to the xoy plane.

During a read or write operation, a corresponding word line may be selected using a word line select signal, and a corresponding bit line may be selected according to a column select signal. When both the word line and the bit line are selected, a selected memory cell may be located. At this point, the transistor of the selected memory cell is turned on due to an operation voltage applied to the word line, so that a read, write, or refresh operation may be performed on the selected memory cell. In some examples, the capacitor may be replaced with other storage structures, including, but not limited to, a phase change storage structure, a resistive storage structure, or a magnetic storage structure, etc.

In some examples, the capacitor represents logic 1 and 0 through an amount of charges stored therein or a magnitude of voltage difference between two ends of the capacitor. A voltage signal on the word line is applied to the gate to control on or off of the transistor, thereby achieving selection and non-selection of the capacitor, such that data information stored in the capacitor is read through the bit line, or data is written to the capacitor through the bit line for storage.

In conjunction with FIG. 1, the second semiconductor sub-structure 120 may include a DRAM memory array, and may include a transistor 121, a capacitor structure 122 coupled with a first active region of the transistor 121 and a bit line 123 coupled with a second active region of the transistor 121. The first active region and the second active region is one of a source and a drain of the transistor 121, and positions of the source and the drain is interchangeable. The transistor 121 may include a gate layer 1212 that may serve as a word line of the DRAM memory array. The examples of the present disclosure may not have limitations to a structure of the transistor 121, which may be a planar transistor or a vertical transistor, extending along the z-direction; and may not have limitations to a structure of the capacitor structure 122, which may include a first electrode 1221, a dielectric layer 1223 and a second electrode 1222. The dielectric layer 1223 electrically isolates the first electrode 1221 and the second electrode 1222, and one electrode of the capacitor structure 122 may extend along the z-direction, and may have a columnar shape.

The first semiconductor sub-structure 110 may include a peripheral circuit that may include, but is not limited to, a CMOS structure 119. The CMOS structure 119 may include, but is not limited to, a CMOS transistor or a device or circuit composed of the CMOS transistor. All device structures of the peripheral circuit are not shown in the figure. The peripheral circuit is configured to control the memory array to perform the read, write or refresh operation. The bit line 123 may be coupled with the bonding contact 115 through a connection structure and/or a routing layer to lead out a signal of the second semiconductor sub-structure 120 and interconnect it with an electrical signal of the peripheral circuit. The gate layer 1212 and the capacitor structure 122 each may lead out the electrical signal through other connection structures and be coupled with the peripheral circuit through the bonding contact 115, to achieve electrical signal interconnection between the memory array and the peripheral circuit.

In an example, the peripheral circuit may include, but is not limited to, a sense amplifier, a row decoder, a column decoder, a voltage generator, etc. The sense amplifier is coupled with the bit line 123, and may be configured to capture weak voltage fluctuation on the bit line 123, and recover a capacitor voltage of the memory cell locally according to the voltage fluctuation. The sense amplifier may include a latch, which may latch the value of the recovered capacitor voltage, such that information stored in the memory cell is transferred from the capacitor to the sense amplifier. The sense amplifier may include a differential sense amplifier that is coupled with two bit lines 123 and operating with a selected bit line 123 and a bit line 123 (e.g., a complimentary bit line) that serves as a reference line, so as to detect and amplify a voltage difference on a pair of bit lines 123. The row decoder is configured to perform row addressing on the memory array and apply an operation voltage to the word line. The column decoder is configured to perform column addressing on the memory array and apply a bit line voltage or receive the bit line voltage. The voltage generator generates high and low voltages required for each device.

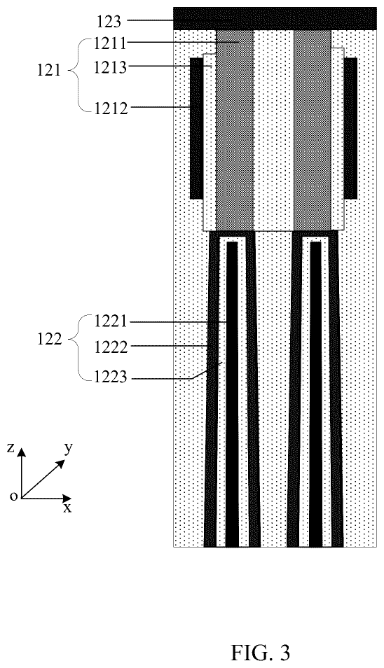

In some examples, as in FIG. 2, the transistor 121 may include a semiconductor pillar 1211 extending along the z-direction. The first active region and the second active region are located at two ends of the semiconductor pillar 1211 that are opposite along the z-direction, respectively. The capacitor structure 122, the semiconductor pillar 1211, the bit line 123, the bonding contact 115 and the first semiconductor sub-structure 110 are arranged sequentially along the z-direction. With reference to the enlarged schematic view of the transistor 121 and the capacitor structure 122 as illustrated in FIG. 3, the semiconductor pillar 1211 extends along the z-direction, and a cross sectional shape of the semiconductor pillar 1211 in the xoy plane may include a rectangle, other quadrangles or other polygons. The semiconductor pillar 1211 have two oppositely disposed ends in the z-direction, i.e., the first active region and the second active region respectively. The first active region is an upper end of the semiconductor pillar 1211 in a positive z-direction in FIG. 3, and is coupled with the bit line 123. The second active region is a lower end of the semiconductor pillar 1211 in a negative z-direction, and is coupled with one electrode of the capacitor structure 122. A dielectric material may be filled between the adjacent semiconductor pillars 1211, and may have an air gap.

The first active region and the second active region of the semiconductor pillar 1211 may have the same type of doping, and an intermediate region between the first active region and the second active region may have an opposite type of doping to the first active region as a channel of the transistor 121. The transistor 121 further includes a gate dielectric layer 1213 covering the channel of the transistor 121 at least along the x-direction. The gate dielectric layer 1213 covers a sidewall of the semiconductor pillar 1211 in the x-direction. The gate layer 1212 covers the gate dielectric layer 1213, and may serve as a control gate of the transistor 121, to which a voltage is applied to control on and off of the transistor 121. The gate layer 1212 may extend along the y-direction and may serve as a word line. One gate layer 1212 may correspond to a plurality of semiconductor pillars 1211 arranged in the y-direction. The bit line 123 extends along the x-direction, and one bit line 123 may correspond to the plurality of semiconductor pillars 1211 arranged in the x-direction. The gate layer 1212 and the bit line 123 are selected, and the semiconductor pillar 1211 corresponding to both the gate layer 1212 and the bit line 123 may be selected, such that the semiconductor pillar 1211 is turned on to select the capacitor structure 122, and operations such as write, refresh or read, etc. are performed by charging and discharging the capacitor structure 122 or sensing the amount of charges of the capacitor structure 122.

In some examples, with continued reference to FIG. 3, the capacitor structure 122 may include a first electrode 1221 extending along the z-direction, a dielectric layer 1223 surrounding the first electrode 1221, and a second electrode 1222 surrounding the dielectric layer 1223. The dielectric layer 1223 is located between the first electrode 1221 and the second electrode 1222, and the second electrode 1222 is coupled with the second active region of the semiconductor pillar 1211. The size in the x-direction of an end of the capacitor structure 122 away from the semiconductor pillar 1211 along the z-direction is greater than or equal to the size in the x-direction of an end of the capacitor structure 122 close to the semiconductor pillar 1211 along the z-direction. With reference to FIG. 1, the first electrodes 1221 of the plurality of capacitor structures 122 may be coupled to an interconnection layer 124 for grounding or accessing to other operation voltages. Alternatively, the plurality of capacitor structures 122 share the first electrode 1221; an end of the first electrode 1221 away from the semiconductor pillar 1211 has a film layer structure extending along the x-direction and/or the y-direction, the first electrode 1221 is grounded or applied with other operation voltages, and the plurality of capacitor structures 122 share the first electrode 1221 and are applied with a common voltage.

In some examples, a contact may be disposed between the capacitor structure 122 and the semiconductor pillar 1211. The semiconductor pillar 1211 is coupled with the capacitor structure 122 through the contact. The contact may include a metal silicide, e.g., titanium silicide, to reduce contact resistance between the semiconductor pillar 1211 and the capacitor structure 122 and increase adhesion strength. The contact may include a multi-layer structure, the portion close to the semiconductor pillar 1211 and the portion in contact with the semiconductor pillar 1211 may include a metal silicide to reduce the contact resistance and increase the adhesion strength, and the portion in contact with the capacitor structure 122 may include a metal to improve electrical connection performance.

In an example, a composition material of the gate layer 1212, the first electrode 1221 and the second electrode 1222 may include, but is not limited to, tungsten, gold, silver, platinum, copper, aluminum, titanium or nickel, or other conductive materials. In addition to the above-mentioned conductive materials, the bit line 123 may further include a doped semiconductor material, e.g., doped silicon, etc. A composition material of the dielectric layer 1223 may include, but is not limited to, silicon oxide, silicon nitride, silicon oxynitride, or aluminum oxide, or other insulation materials.

As the integration density of the integrated circuit is further increased, the number and arrangement density of the first connection sub-structures 1121 and the second connection sub-structures 1122 are increasingly larger to match greater data information interaction, and the requirements for electrical isolation between the first connection sub-structure 1121 and the first semiconductor layer 111 are further increased to reduce the electrical signal interference.

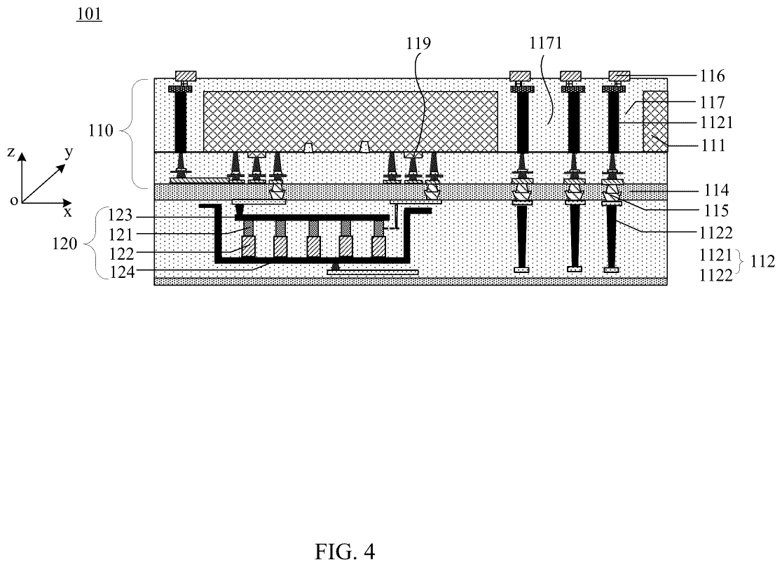

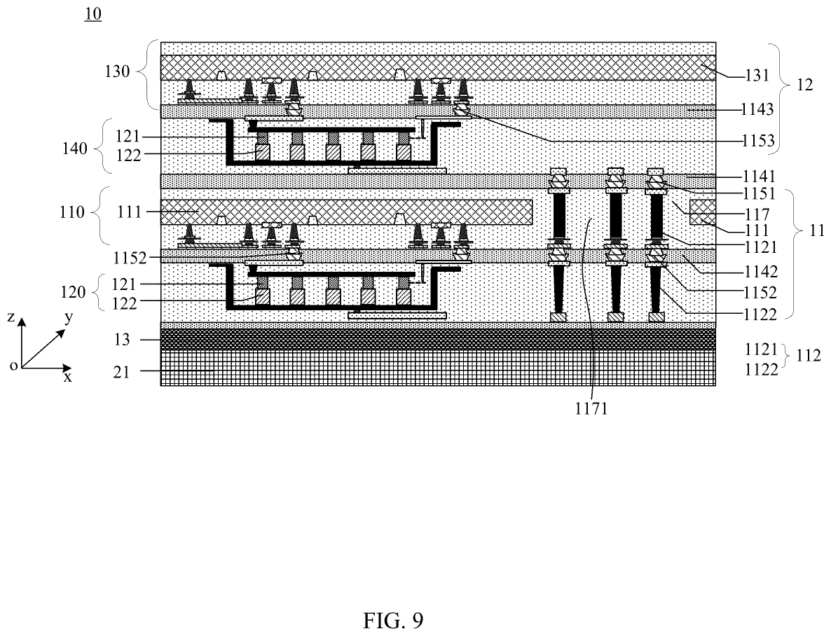

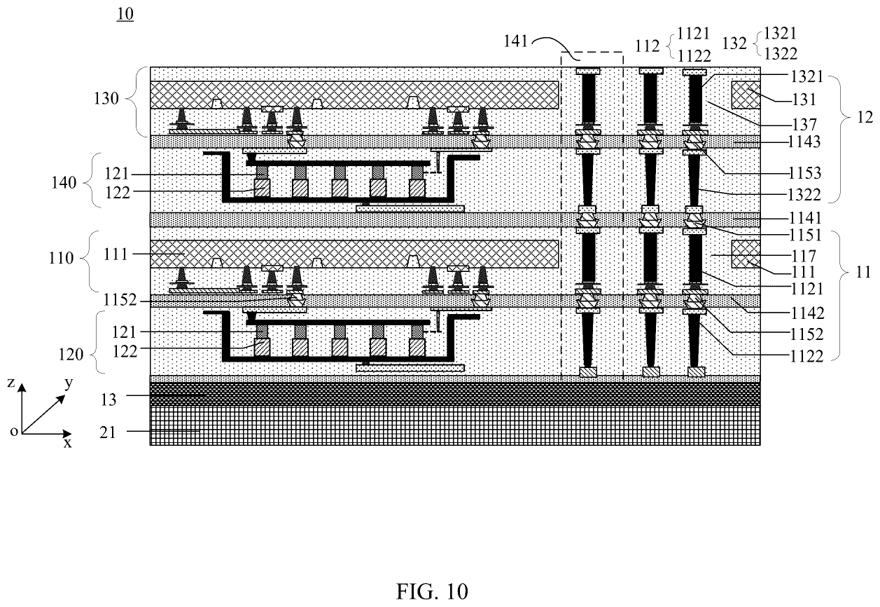

According to some aspects of examples of the present disclosure, FIG. 4 provides a semiconductor structure 101. The semiconductor structure 101 may be a first semiconductor chip 11 of FIGS. 9 and 10 below, or part of a semiconductor chip, and includes a first semiconductor sub-structure 110 and a second semiconductor sub-structure 120 that are bonded in a first direction (the z-direction). The first semiconductor sub-structure 110 includes a first semiconductor layer 111, and a plurality of first connection sub-structures 1121 extending through the first semiconductor layer 111 along the z-direction. A dielectric material is between any two of the first connection sub-structures 1121 for isolation, and is in contact with any two of the first connection sub-structures 1121.

The semiconductor structure 101 further includes a pad 116 that is located on a side of the first semiconductor sub-structure 110 away from the second semiconductor sub-structure 120 and is coupled with the first connection sub-structure 1121.

In some examples, with reference to FIG. 4, the first semiconductor sub-structure 110 includes a first isolation structure 117 extending through the first semiconductor layer 111 along the z-direction. The first isolation structure 117 includes a dielectric material, and the plurality of first connection sub-structures 1121 extend through the first isolation structure 117 along the z-direction.

With reference to FIG. 4, the dielectric material 1171 between any two adjacent ones of the first connection sub-structures 1121 electrically isolate the first connection sub-structures 1121 to reduce electrical leakage and interference between the first connection sub-structures 1121. There is no first semiconductor layer 111 between any adjacent ones of the first connection sub-structures 1121. The dielectric material 1171 may be located between the first connection sub-structure 1121 and the first semiconductor layer 111 to reduce the electrical leakage and interference between the first connection sub-structure 1121 and the first semiconductor layer 111. The dielectric material 1171 may also cover the first semiconductor layer 111. The dielectric material 1171 may include, but is not limited to, silicon oxide, silicon nitride, silicon oxynitride, aluminum oxide, spin-coated dielectric material, and other insulation materials.

With reference to FIG. 4, the first isolation structure 117 extending through the first semiconductor layer 111 may be provided, and may include a portion of the dielectric material 1171, that is, a portion extending through the first semiconductor layer 111 along the z-direction is the first isolation structure 117, and the first isolation structure 117 may not have a physical boundary with the other portions of the dielectric material 1171. Alternatively, some portions, some film layers or some structures of the dielectric material 1171 include the first isolation structure 117. In an example, during the formation of the first isolation structure 117, the first semiconductor layer 111 is etched to form a groove which is filled with the dielectric material 1171 and in which the first isolation structure 117 is formed. During deposition and filling of the dielectric material 1171, part of the dielectric material 1171 may cover the first semiconductor layer 111. The plurality of first connection sub-structures 1121 extend through the first isolation structure 117. Alternatively, the first semiconductor layer 111 has an insulation region, and the plurality of first connection sub-structures 1121 extend through the insulation region to reduce electrical leakage between the first connection sub-structures 1121 and the first semiconductor layer 111. The first isolation structure 117 may be positioned in any region of the semiconductor layer, for example, close to an edge region, according to design requirements of an actual chip or package. The cross sectional shape of the first isolation structure 117 in the xoy plane may include, but is not limited to, a rectangle (or strip), a circle or an ellipse, and may also include a closed polygon with the first semiconductor layer 111 exposed at its center. The cross sectional shape of the first isolation structure 117 in the xoz plane may include, but is not limited to, a rectangle or other polygons.

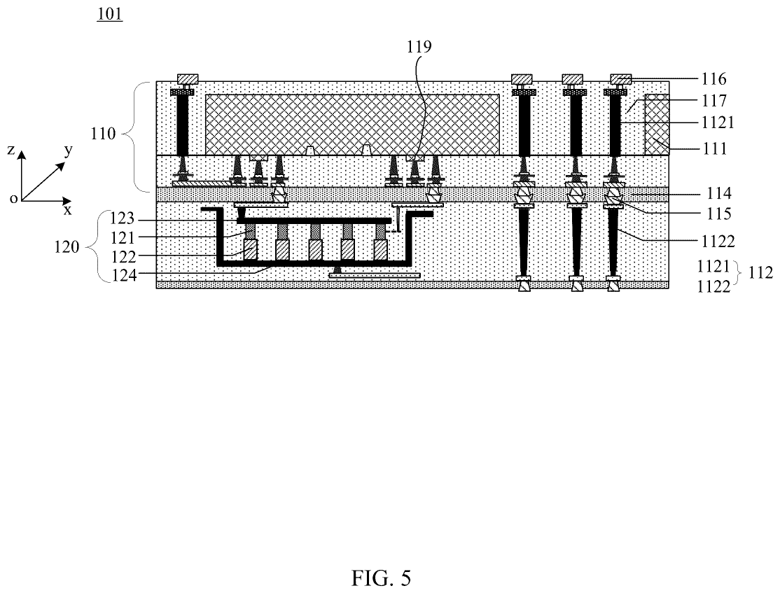

With reference to FIG. 5, the pads 116 are disposed on two sides of the semiconductor structure 101 that are opposite along the z-direction. The semiconductor structure 101 may serve as a second semiconductor chip 12 or part of the second semiconductor chip 12 in FIG. 10 below. The pad 116 serves as a bonding pad to be bonded with other semiconductor chips.

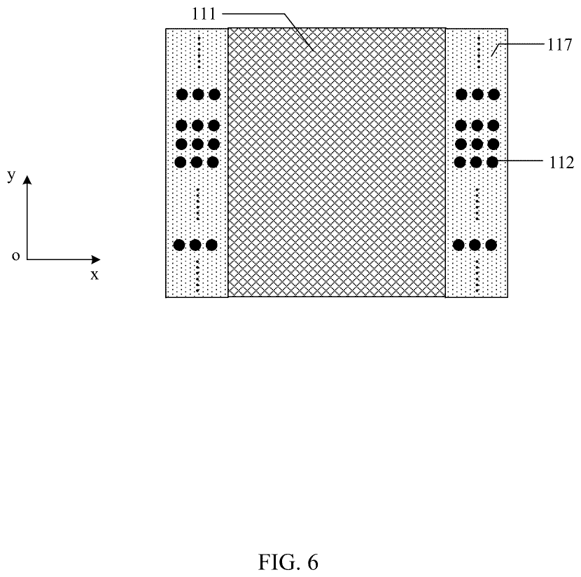

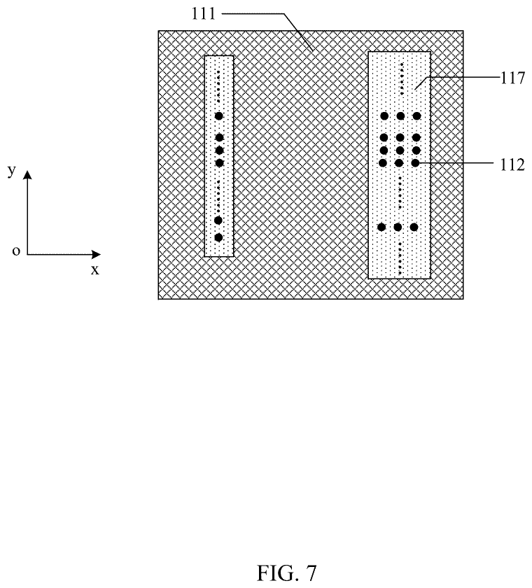

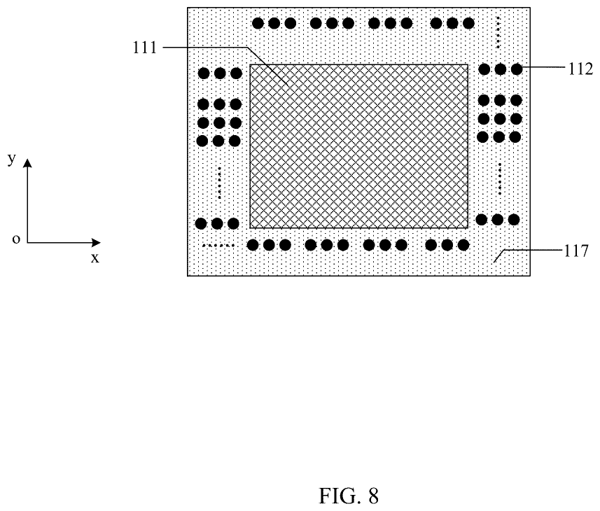

In some examples, FIGS. 6 to 8 illustrates an example of arrangement of the first isolation structure 117 relative to the first semiconductor layer 111. With reference to FIG. 6, the first isolation structure 117 may be disposed at an edge region of the first semiconductor layer 111, corresponding to an edge region of the first semiconductor sub-structure 110. The first isolation structure 117 may be rectangular. The plurality of first connection sub-structures 1121 extend through the first isolation structure 117, and the number and the arrangement of the first connection sub-structures 1121 are not limited herein. With reference to FIG. 7, the first isolation structure 117 may be disposed in any region of the first semiconductor layer 111, and is embedded within the range of film layer of the first semiconductor layer 111. With reference to FIG. 8, the first isolation structure 117 may surround the first semiconductor layer 111, and the contour shape of the first isolation structure 117 may include a rectangle or other polygons.

A composition material of the first isolation structure 117 may include, but is not limited to, silicon oxide, silicon nitride, silicon oxynitride or aluminum oxide, or other insulation materials. The first semiconductor layer 111 is further covered with a dielectric material layer. When the dielectric material layer and the first isolation structure 117 have the same composition material, the first isolation structure 117 may have no physical boundary with the dielectric material layer. The first isolation structure 117 may have no physical boundary with the dielectric material layer under the first semiconductor layer 111.

In some examples, the pad 116 is coupled with the first connection sub-structure 1121, and may serve as a bonding pad to be coupled with other semiconductor structures 101, or serve as an IO interface for power supply or data transmission.

Compared with the first connection sub-structure 1121 and the isolation layer 113 surrounding the first connection sub-structure 1121 shown in FIG. 2, as shown in FIG. 4, the plurality of first connection sub-structures 1121 extend through the first isolation structure 117, and no semiconductor layer is between adjacent ones of the first connection sub-structures 1121. An insulation structure is between adjacent ones of the first connection sub-structures 1121, which can further reduce the electrical leakage and interference between the first connection sub-structures 1121. Moreover, compared with a film layer, the first isolation structure 117 may be set with a larger lateral size, e.g., a size in the x and y-directions, and the first isolation structure 117 may provide a thicker size for insulation between the first connection sub-structure 1121 and the first semiconductor layer 111, thereby improving the insulation performance and reducing the electrical leakage and interference.

In some examples, with reference to FIG. 4, the first semiconductor sub-structure 110 and the second semiconductor sub-structure 120 are coupled by a plurality of bonding contacts 115 extending through a dielectric layer 114 and the first connection sub-structure 1121, and the first connection sub-structure 1121 is coupled with the bonding contact 115. The dielectric layer 114 may include a second dielectric layer 1142 in FIG. 9. The bonding contact 115 may include a second bonding contact 1152 extending through the second dielectric layer 1142 in FIG. 9. The dielectric layer 114 may further include a third dielectric layer 1143 as shown in FIG. 10. The bonding contact 115 may include a third bonding contact 1153 extending through the third dielectric layer 1143 in FIG. 10.

Two bonding layers on a surface to be bonded of the first semiconductor sub-structure 110 and on the second semiconductor sub-structure 120 respectively before the bonding are bonded to form the dielectric layer 114. The bonding layers may not have a physical boundary after the bonding. The dielectric layer 114 may be considered as a bonding layer or a bonding interface formed after bonding two film layers. A contact to be bonded of the first semiconductor sub-structure 110 and a contact to be bonded of the second semiconductor sub-structure 120 may not have a physical boundary after bonding, and may be considered as the bonding contact 115 in FIG. 4. The bonding contact 115 extends through the bonding interface and the dielectric layer 114. The first semiconductor sub-structure 110 and the second semiconductor sub-structure 120 may achieve electrical signal interconnection through the first connection sub-structure 1121 and the bonding contact 115.

In some examples, with reference to FIG. 4, the second semiconductor sub-structure 120 further includes a second connection sub-structure 1122 extending along the z-direction. The bonding contact 115 is located between the first connection sub-structure 1121 and the second connection sub-structure 1122, and the first connection sub-structure 1121 and the second connection sub-structure 1122 are coupled by the bonding contact 115. The first connection sub-structure 1121 and the second connection sub-structure 1122 are coupled by the bonding contact 115, to achieve electrical signal interconnection between the first semiconductor sub-structure 110 and the second semiconductor sub-structure 120. The first connection sub-structure 1121 may be coupled with the bonding contact 115 through a conductive structure such as a conductive plug, etc. In some examples, the second connection sub-structure 1122, the bonding contact 115 and the first connection sub-structure 1121 may have the same composition material, may not have an obvious boundary after undergoing processes such as thermal treatment, etc., and may be regarded approximately as a connection structure extending along the z-direction in terms of its actual physical structure.

In some examples, with reference to FIG. 4, the size in a second direction (the x-direction) of an end of the first connection sub-structure 1121 away from the second semiconductor sub-structure 120 along the z-direction is greater than or equal to the size in the x-direction of an end of the first connection sub-structure 1121 close to the second semiconductor sub-structure 120. The x-direction intersects the z-direction and may be perpendicular to the z-direction. In an example, the first isolation structure 117 is etched along a direction toward the second semiconductor sub-structure 120 to form an opening, and the first connection sub-structure 1121 is formed in the opening. A loading effect of the etching is due to the fact that the size of an open end of the opening in the x-direction is greater than or equal to the size of a bottom of the opening, such that the size in the x-direction of an end of the first connection sub-structure 1121 exposed at the first isolation structure 117 of FIG. 4 or an end of the first connection sub-structure 1121 coupled with the pad 116 is greater than or equal to that of the other end coupled with the bonding contact 115.

In some examples, with reference to FIGS. 3 and 4, the second semiconductor sub-structure 120 includes a transistor 121 including a first active region, a second active region and a gate layer 1212; a bit line 123 coupled with the first active region; and a capacitor structure 122 coupled with the second active region.

In some examples, the transistor 121 includes a semiconductor pillar 1211 extending along the z-direction. The first active region and the second active region are located at two ends of the semiconductor pillar 1211 that are opposite in the z-direction, and the gate layer 1212 extends along a direction intersecting the z-direction and covers part of a side of the semiconductor pillar 1211. The transistor 121 further includes a gate dielectric layer 1213 between the gate layer 1212 and the semiconductor pillar 1211. The bit line 123 may extend along the x-direction, and the gate layer 1212 may extend along the y-direction. The x-direction intersects, e.g., is perpendicular to, the y-direction, and the z-direction is perpendicular to the xoy plane.

The schematic diagrams of the transistor 121 and the capacitor structure 122 is illustrated in FIG. 3. The first active region and the second active region may be an upper end and a lower end of the semiconductor pillar 1211 that are opposite along the z-direction, respectively. A region of the semiconductor pillar 1211 between the first active region and the second active region serves as a channel of the transistor 121. In some examples, one semiconductor pillar 1211 may correspond to one gate layer 1212, and is located on one side of the semiconductor pillar 1211 in the x-direction. Alternatively, one semiconductor pillar 1211 may have two gate layers 1212 located respectively on two sides of the semiconductor pillar 1211 that are opposite in the x-direction. Alternatively, part of the gate layer 1212 surrounds three or four sides of the semiconductor pillar 1211, and the other part of the gate layer 1212 extends along the y-direction. The capacitor structure 122 may include a first electrode 1221 extending along the z-direction, a dielectric layer 1223 surrounding the first electrode 1221, and a second electrode 1222 surrounding the dielectric layer 1223. The dielectric layer 1223 is located between the first electrode 1221 and the second electrode 1222, and the second electrode 1222 is coupled with the second active region of the semiconductor pillar 1211.

In some examples, the second semiconductor sub-structure 120 includes a peripheral circuit coupled with the bit line 123 through part of the bonding contacts 115 and with the gate layer 1212 through another part of the bonding contacts 115. The peripheral circuit may include, but is not limited to, a CMOS structure 119 that may include, but is not limited to, a CMOS transistor or a device or circuit composed of the CMOS transistor. The peripheral circuit is coupled with the bit line 123 and the gate layer 1212 through different bonding contacts 115, and is configured to control a memory array to perform a read, write or refresh operation. The bit line 123 may be coupled with the bonding contact 115 through a connection structure and/or a routing layer to lead out a signal of the second semiconductor sub-structure 120 and interconnect it with an electrical signal of the peripheral circuit. The gate layer 1212 and the capacitor structure 122 each may lead out the electrical signal through other connection structures and be coupled with the peripheral circuit through the bonding contact 115, to achieve electrical signal interconnection between the memory array and the peripheral circuit.

In some examples, a composition material of the dielectric layer 114 includes carbon-doped silicon nitride.

A composition material of the dielectric layer 114 as a bonding layer or a bonding interface may include, but is not limited to, silicon oxide, silicon nitride, silicon oxynitride, carbon-doped silicon nitride and other insulation materials. The dielectric layer 114 provides electrical isolation for the plurality of bonding contacts 115. The dielectric layer 114 provides a larger bonding area to provide a larger bonding force, and the carbon-doped silicon nitride provides a smoother bonding plane and greater bonding strength.

In some examples, a composition material of the pad 116 includes at least one of aluminum, copper, nickel, titanium, tungsten, gold, silver and platinum and other conductive materials. The cross sectional shape of the pad 116 in the xoy plane may include, but is not limited to, a rectangle or other polygons, a circle or an ellipse, etc. When one semiconductor structure 101 shown in FIG. 4 or FIG. 1 is applied in an integrated circuit after packaging, the pad 116 may serve as an IO interface that is coupled with an external integrated circuit for power supply or data interaction. When a plurality of semiconductor structures 101 shown in FIG. 4, FIG. 1 or FIG. 5 are stacked along the z-direction to form a stack structure, and the stack structure is applied in an integrated circuit after packaging, the pad 116 may serve as a bonding pad or a bonding contact 115 that is bonded with other pads 116 to achieve stacking in the z-direction, and is combined with a plurality of connection structures to achieve electrical signal interconnection of the plurality of semiconductor structures 101.

According to some aspects of examples of the present disclosure, FIG. 9 provides a semiconductor structure 10 including a first semiconductor chip 11 and a second semiconductor chip 12 that are bonded along the z-direction. The first semiconductor chip 11 includes a first semiconductor layer 111 and a plurality of first connection structures 112 extending through the first semiconductor layer 111 along the z-direction. A dielectric material 1171 is between and in contact with any two of the first connection structures 112.

The first semiconductor chip 11 and the second semiconductor chip 12 are coupled by a plurality of first bonding contacts 1151 extending through a first dielectric layer 1141 and the plurality of first connection structures 112, and the first connection structures 112 are coupled with the first bonding contacts 1151. In an example, the semiconductor structure 10 of FIG. 9 may include a first semiconductor chip 11 and a second semiconductor chip 12. The first semiconductor chip 11 and the second semiconductor chip 12 may include the semiconductor structure 101 of FIG. 1, FIG. 4 or FIG. 5.

In some examples, the first semiconductor chip 11 includes a first isolation structure 117 extending through the first semiconductor layer 111 along the z-direction. The first isolation structure 117 includes a dielectric material 1171, and the plurality of first connection structures 112 extend through the first isolation structure 117 along the z-direction. The first isolation structure 117 may include a portion of the dielectric material 1171, i.e., a portion extending through the first semiconductor layer 111 along the z-direction is the first isolation structure 117, and the first isolation structure 117 may not have a physical boundary with the other portions of the dielectric material 1171. Alternatively, some portions, some film layers or some structures of the dielectric material 1171 include the first isolation structure 117. The dielectric material 1171 may cover the first semiconductor layer 111.

The first semiconductor chip 11 shown in FIG. 9 may include the structure shown in FIG. 4. The first semiconductor chip 11 is located under the second semiconductor chip 12, the first semiconductor chip 11 and the second semiconductor chip 12 are coupled and fixed by hybrid bonding, and the first semiconductor chip 11 may achieve electrical signal interconnection through the plurality of first bonding contacts 1151 extending through the first dielectric layer 1141. The electrical signal interconnection may include, but is not limited to, power supply, control signal interaction, data transmission, etc.

The first dielectric layer 1141 is formed after bonding two dielectric layers to be bonded at the two semiconductor chips respectively and may not have a physical boundary. The bonding contact 115 is formed after bonding two bonding contacts to be bonded at the two semiconductor chips respectively and may not have a physical boundary. The bonding contact 115 may include, but is not limited to, a conductive pad structure such as a pad 116 (e.g., a conductive pad).

The first semiconductor layer 111 is located on a side of the first semiconductor chip 11 close to the second semiconductor chip 12. The first isolation structure 117 is located on a side of the first semiconductor chip 11 close to the second semiconductor chip 12. The plurality of first connection structures 112 extend through the first isolation structure 117 and are coupled with the first bonding contacts 1151. The first connection structure 112 is located in the first semiconductor chip 11 and on a side of the first bonding contact 1151 away from the second semiconductor chip 12. The first connection structure 112 may lead out an electrical signal of the first semiconductor chip 11 to the first bonding contact 1151 to achieve electrical signal interconnection with the second semiconductor chip 12.

In some examples, the first connection structure 112 may include a plurality of sub-structures stacked and coupled in the z-direction, or may include a single structure. For example, when the first semiconductor chip 11 includes a first semiconductor sub-structure 110 and a second semiconductor sub-structure 120 that are bonded together, a first connection sub-structure 1121 in the first semiconductor sub-structure 110 and a second connection sub-structure 1122 in the second semiconductor sub-structure 120 are coupled by bonding. In some examples, when the first semiconductor sub-structure 110 and the second semiconductor sub-structure 120 in the first semiconductor chip 11 are not bonded, the first semiconductor sub-structure 110 is formed on the second semiconductor sub-structure 120 without providing any bonding contact. The first connection sub-structure 1121 and the second connection sub-structure 1122 may be in contact and coupled directly and not have a physical boundary, and may also include more levels of connection sub-structures. In some examples, when the first semiconductor chip 11 does not have a plurality of bonded and stacked structures and the thickness of the first semiconductor chip 11 in the z-direction is small, the height of leads of the first semiconductor chip 11 in the z-direction is small; alternatively, a single layer of the first connection structure 112 may be directly disposed in the first semiconductor chip 11 and extends along the z-direction, and the first connection structure 112 extends through the first isolation structure 117 at least along the z-direction and may extend to any position of film layer of the first semiconductor chip 11.

In some examples, with reference to FIG. 9, when no chip is stacked over the second semiconductor chip 12, in the second semiconductor chip 12, it is not necessary to disposed a connection structure extending along the z-direction, a connection structure extending through the second semiconductor layer 131, and a second isolation structure 137. The second semiconductor chip 12 leads out its electrical signal through the first bonding contact 1151 for the electrical signal interconnection with the first semiconductor chip 11. The first bonding contact 1151 may be coupled with some interconnection layers of the second semiconductor chip 12 and be coupled with some interconnection layers of the first semiconductor chip 11 to achieve electrical signal lead-out and interconnection of the two semiconductor chips. These interconnection layers or routing layers are not completely shown in FIG. 9. The first semiconductor chip 11 may be disposed on an intermediary substrate 21, and coupled with the intermediary substrate 21 for packaging. The intermediary substrate 21 may be coupled with an external integrated circuit and provides electrical signal interconnection for the first semiconductor chip 11. The first semiconductor chip 11 and the second semiconductor chip 12 achieve electrical signal interconnection through the first connection structure 112 and the first bonding contact 1151. A third semiconductor chip 13 may be disposed between the intermediary substrate 21 and the first semiconductor chip 11, and may include, but is not limited to, a logic control circuit. The third semiconductor chip 13 is bonded and coupled with the first semiconductor chip 11 and may control the first semiconductor chip 11. The third semiconductor chip 13 controls the second semiconductor chip 12 through the first connection structure 112 and the first bonding contact 1151. The third semiconductor chip 13 may be a logic chip, including, but not limited to, a control logic, an interface control module, an SRAM cache and other assemblies. The third semiconductor chip 13 has a third connection structure extending along the z-direction. The third connection structure may be a through silicon via (TSV), and may be bonded and coupled with the first connection structure 112 through the bonding contacts therebetween to achieve vertical electrical signal interconnection.

In the examples of the present disclosure, there is no semiconductor layer between adjacent ones of the first connection structures 112, and an insulation structure is between adjacent ones of the first connection structures 112, which can further reduce electrical leakage and interference between the first connection structures 112. Moreover, compared with a film layer, the first isolation structure 117 may be set with a larger lateral size, e.g., a size in x and y-directions, and the first isolation structure 117 may provide a thicker size for insulation between the first connection structure 112 and the first semiconductor layer 111, thereby improving the insulation performance and reducing the electrical leakage and interference.

In some examples, with reference to FIG. 9, the size in the x-direction of an end of the first connection structure 112 close to the second semiconductor chip 12 along the z-direction is greater than or equal to the size in the x-direction of an end of the first connection structure 112 away from the second semiconductor chip 12, and the x-direction intersects the z-direction. The size in the x-direction and/or the y-direction of an end of the first connection structure 112 close to the first bonding contact 1151 in the z-direction is greater than or equal to that of an end of the first connection structure 112 away from the first bonding contact 1151.

In some examples, with reference to FIG. 9, the first semiconductor chip 11 includes a first semiconductor sub-structure 110 and a second semiconductor sub-structure 120 that are bonded along the z-direction. The first semiconductor layer 111 is located in the first semiconductor sub-structure 110 and between the second semiconductor sub-structure 120 and the second semiconductor chip 12. The first semiconductor sub-structure 110 and the second semiconductor sub-structure 120 are coupled by a plurality of second bonding contacts 1152 extending through a second dielectric layer 1142. The first connection structure 112 includes a first connection sub-structure 1121 in the first semiconductor sub-structure 110 and a second connection sub-structure 1122 in the second semiconductor sub-structure 120. The second bonding contacts 1152 are located between the first connection sub-structure 1121 and the second connection sub-structure 1122, and the first connection sub-structure 1121 and the second connection sub-structure 1122 are coupled by the second bonding contacts 1152.

The first semiconductor sub-structure 110 and the second semiconductor sub-structure 120 may achieve electrical signal interconnection through part of the second bonding contacts 1152, and the first semiconductor chip 11 and the second semiconductor chip 12 may achieve electrical signal interconnection through the second connection sub-structure 1122, another part of the second bonding contacts 1152, the first connection sub-structure 1121 and the first bonding contact 1151. The size in the x-direction and/or the y-direction of an end of the first connection sub-structure 1121 close to the first bonding contact 1151 is greater than or equal to that of an end of the first connection sub-structure away from the first bonding contact 1151. The size in the x-direction and/or the y-direction of an end of the second connection sub-structure 1122 close to the second bonding contact 1152 is greater than or equal to that of an end of the second connection sub-structure away from the second bonding contact 1152.

In some examples, with reference to FIG. 9, the second semiconductor chip 12 includes a third semiconductor sub-structure 130 and a fourth semiconductor sub-structure 140 that are bonded in the z-direction. The fourth semiconductor sub-structure 140 is located between the first semiconductor chip 11 and the third semiconductor sub-structure 130. The fourth semiconductor sub-structure 140 and the third semiconductor sub-structure 130 are coupled by a plurality of third bonding contacts 1153 extending through a third dielectric layer 1143, and the third dielectric layer 1143 and the first dielectric layer 1141 are located on two sides of the fourth semiconductor sub-structure 140 that are opposite in the z-direction. The fourth semiconductor sub-structure 140 may include the same or similar device structures as the second semiconductor sub-structure 120, for example, both of them may include a transistor 121 and a capacitor structure 122 coupled with the transistor 121. The third semiconductor sub-structure 130 may include the same or similar device structure as the first semiconductor sub-structure 110, for example, both of them may include a peripheral circuit that may include a CMOS structure 119. The first semiconductor chip 11 serves as a DRAM chip, the second semiconductor chip 12 serves as a DRAM chip, and the two semiconductor chips are bonded and achieve electrical signal interconnection through the second connection sub-structure 1122, the second bonding contact 1152, the first connection sub-structure 1121 and the first bonding contact 1151. It may be understood that the first semiconductor chip 11 and the second semiconductor chip 12 shown in FIG. 9 may serve as DRAM separately to store data before bonding.

In some examples, with reference to FIG. 10, the second semiconductor chip 12 further includes a second connection structure 132 extending along the z-direction. The second connection structure 132 is located between the first bonding contact 1151 and the third bonding contact 1153. The second connection structure 132 is coupled with the first bonding contact 1151 and the third bonding contact 1153. The second connection structure 132 may be only located in the fourth semiconductor sub-structure 140 and between the first bonding contact 1151 and the third bonding contact 1153, and is coupled with the first bonding contact 1151 and the third bonding contact 1153.

In some examples, with reference to FIG. 10, the second connection structure 132 includes a third connection sub-structure 1321 in the third semiconductor sub-structure 130 and a fourth connection sub-structure 1322 in the fourth semiconductor sub-structure 140. The third bonding contact 1153 is located between the third connection sub-structure 1321 and the fourth connection sub-structure 1322, and the third connection sub-structure 1321 is coupled with the fourth connection sub-structure 1322 through the third bonding contact 1153. The second connection sub-structure 1122, the second bonding contact 1152, the first connection sub-structure 1121, the first bonding contact 1151, the fourth connection sub-structure 1322, the third bonding contact 1153 and the third connection sub-structure 1321 that are stacked and coupled sequentially along the z-direction constitute a conductive channel 141 for electrical signal interconnection between the first semiconductor chip 11 and the second semiconductor chip 12. The second semiconductor layer 131 of the second semiconductor chip 12 is located on a side of the second semiconductor chip 12 away from the first semiconductor chip 11, and may be located in the third semiconductor sub-structure 130. When no other semiconductor chips are stacked on the second semiconductor chip 12, the second connection structure 132 (or the third connection sub-structure 1321) does not extend through the second semiconductor layer 131, or the second isolation structure 137 extending through the second semiconductor layer 131 need not be provided, or the third connection sub-structure 1321 extending through the second isolation structure 137 need not be provided.

In some examples, with reference to FIG. 10, the third semiconductor sub-structure 130 further includes: a second semiconductor layer 131, and a second isolation structure 137 extending through the second semiconductor layer 131 along the z-direction. The plurality of third connection sub-structures 1321 extend through the second isolation structure 137. The second semiconductor chip 12 may have the same or similar structure as the first semiconductor chip 11, and may include the structure shown in FIG. 4. A pad 116 is disposed on a side of the third connection sub-structure 1321 away from the third bonding contact 1153, and may serve as a bonding pad to be coupled with other semiconductor structures 101, or serve as an IO interface for power supply or data transmission.

In some examples, with reference to FIG. 10, the second semiconductor sub-structure 120 and the fourth semiconductor sub-structure 140 each include: a transistor 121 including a first active region, a second active region and a gate layer 1212; a bit line 123 coupled with the first active region; and a capacitor structure 122 coupled with the second active region. In some examples, the transistor 121 includes a semiconductor pillar 1211 extending along the z-direction. The first active region and the second active region are located at two ends of the semiconductor pillar 1211 that are opposite in the first direction. The gate layer 1212 extends along a direction intersecting the first direction, and covers part of a side of the semiconductor pillar 1211. The transistor 121 further includes a gate dielectric layer 1213 between the gate layer 1212 and the semiconductor pillar 1211. The bit line 123 may extend along the x-direction, and the gate layer 1212 may extend along the y-direction. The x-direction intersects, e.g., is perpendicular to, the y-direction, and the z-direction is perpendicular to the xoy plane.

The transistor 121 and the capacitor structure 122 may be as illustrated in FIG. 3. The first active region and the second active region may be an upper end and a lower end of the semiconductor pillar 1211 that are opposite along the z-direction, respectively. A region of the semiconductor pillar 1211 between the first active region and the second active region serves as a channel of the transistor 121. The capacitor structure 122 may include a first electrode 1221 extending along the z-direction, a dielectric layer 1223 surrounding the first electrode 1221, and a second electrode 1222 surrounding the dielectric layer 1223. The dielectric layer 1223 is located between the first electrode 1221 and the second electrode 1222, and the second electrode 1222 is coupled with the second active region of the semiconductor pillar 1211. The transistor 121, the capacitor structure 122, the bit line 123 and other interconnection layers or conductive structures may constitute a DRAM memory array.

In some examples, with reference to FIG. 10, the first semiconductor sub-structure 110 and the third semiconductor sub-structure 130 each include a peripheral circuit coupled with the bit line 123 by part of the second bonding contacts 1152 and coupled with the gate layer 1212 by another part of the second bonding contacts 1152. The peripheral circuit in the first semiconductor sub-structure 110 controls the DRAM memory array in the second semiconductor sub-structure 120, and may constitute a first DRAM chip; and the peripheral circuit in the third semiconductor sub-structure 130 controls the DRAM memory array in the fourth semiconductor sub-structure 140, and may constitute a second DRAM chip. The first semiconductor chip 11 serves as a DRAM chip, and the second semiconductor chip 12 serves as a DRAM chip. Both of them may serve as a DRAM to store data before bonding. The two semiconductor chips are bonded and achieve electrical signal interconnection through a conductive channel 141 constituted by the second connection sub-structure 1122, the second bonding contact 1152, the first connection sub-structure 1121, the first bonding contact 1151, the fourth connection sub-structure 1322, the third bonding contact 1153 and the third connection sub-structure 1321. The pad 116 may serve as a bonding pad to be coupled with other semiconductor structures 101, or serve as an IO interface for power supply or data transmission.

In some examples, with reference to FIGS. 9 and 10, the semiconductor structure 101 further includes a third semiconductor chip 13 that is located on a side of the first semiconductor chip 11 away from the second semiconductor chip 12. The third semiconductor chip 13 includes a control logic circuit and is bonded with the first semiconductor chip 11, and the first connection structure 112 is coupled with the third semiconductor chip 13. The third semiconductor chip 13 may be a logic chip.

In some examples, with reference to FIGS. 9 and 10, the semiconductor structure 101 further includes an intermediary substrate 21 on a side of the third semiconductor chip 13 away from the first semiconductor chip 11. The third semiconductor chip 13 is coupled with the intermediary substrate 21. The first semiconductor chip 11 may be disposed on an intermediary substrate 21, and coupled with the intermediary substrate 21 for packaging. The intermediary substrate 21 may be coupled with an external integrated circuit and provides electrical signal interconnection for the first semiconductor chip 11. The first semiconductor chip 11 achieves electrical signal interconnection with the second semiconductor chip 12 through the first connection structure 112 and the first bonding contact 1151. The third semiconductor chip 13 may be disposed between the intermediary substrate 21 and the first semiconductor chip 11, and may include, but is not limited to, a logic control circuit. The third semiconductor chip 13 is bonded and coupled with the first semiconductor chip 11, and may control the first semiconductor chip 11. The third semiconductor chip 13 may achieve electrical signal interconnection with the first semiconductor chip 11 and the second semiconductor chip 12 through a conductive channel 141 constituted by the second connection sub-structure 1122, the second bonding contact 1152, the first connection sub-structure 1121, the first bonding contact 1151, the fourth connection sub-structure 1322, the third bonding contact 1153 and the third connection sub-structure 1321. The third semiconductor chip 13 may separately control the first semiconductor chip 11 and the second semiconductor chip 12 to perform operations such as read, refresh, etc., or may simultaneously control the first semiconductor chip 11 and the second semiconductor chip 12 to perform operations such as read, refresh, etc. The intermediary substrate 21 may include, but is not limited to, a silicon intermediary plate, or other substrates and materials applied to the package.

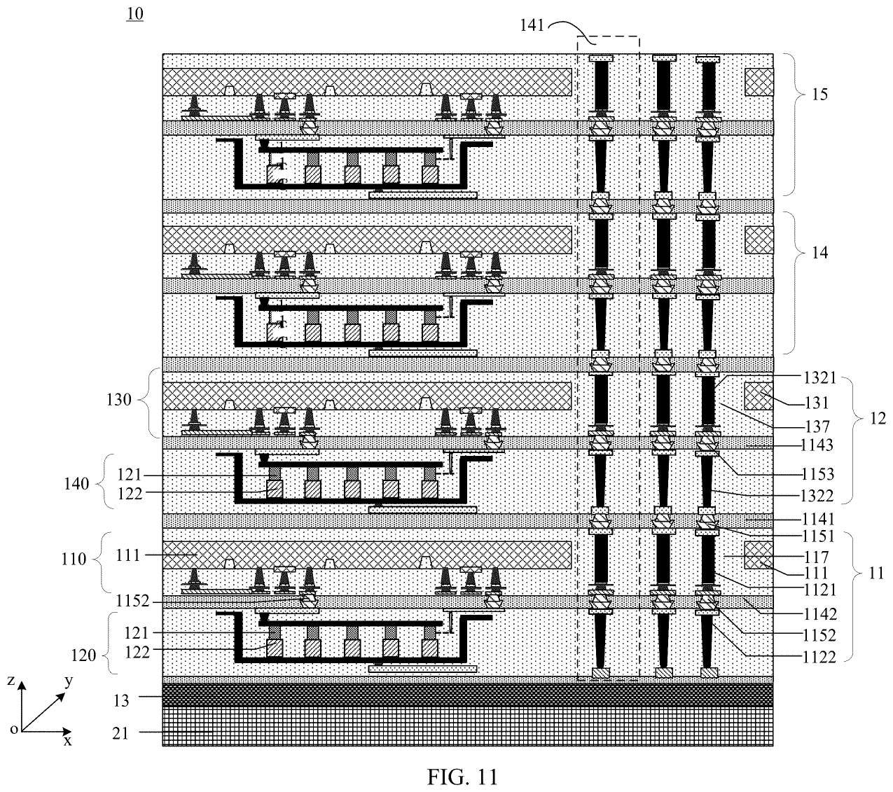

In some examples, more semiconductor chips may be bonded, the connection structure extending along the z-direction is provided for the electrical signal interconnection, and a logic circuit of the third semiconductor chip 13 independently controls each semiconductor chip through the connection structure in the z-direction. With reference to FIG. 11, the third semiconductor chip 13 has a plurality of semiconductor chips stacked thereon. The semiconductor chips are coupled through the bonding contact 115 for the electrical signal interconnection. For example, the first semiconductor chip 11, the second semiconductor chip 12, the fourth semiconductor chip 14, the fifth semiconductor chip 15 or more semiconductor chips are sequentially disposed on the third semiconductor chip 13 by bonding, and achieve electrical signal interconnection through the conductive channel 141. Structures of the fourth semiconductor chip 14 and the fifth semiconductor chip 15 may be referred to what is shown in FIG. 10. The conductive channel 141 may include a plurality of connection structures that may be coupled through the bonding contacts. Taking the first semiconductor chip 11 and the second semiconductor chip 12 as an example, the second connection sub-structure 1122, the second bonding contact 1152, the first connection sub-structure 1121, the first bonding contact 1151, the fourth connection sub-structure 1322, the third bonding contact 1153 and the third connection sub-structure 1321 may achieve electrical signal interconnection. The third semiconductor chip 13 may control the first semiconductor chip, second semiconductor chip, the fourth semiconductor chip and the fifth semiconductor chip to perform operation such as read, refresh, etc. through the conductive channel 141. The plurality of conductive channels 141 may be configured for power supply, control signal transmission and user data transmission, and may be applied in, but is not limited to, a high bandwidth memory product such as an HBM, etc.

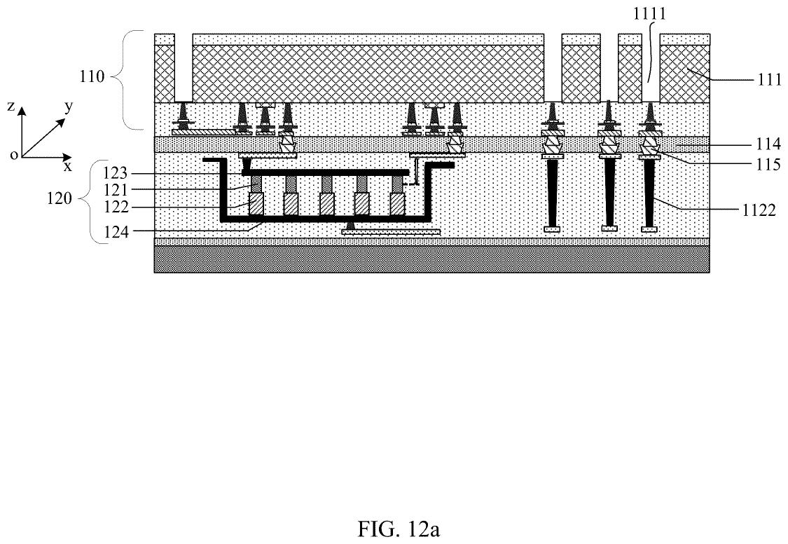

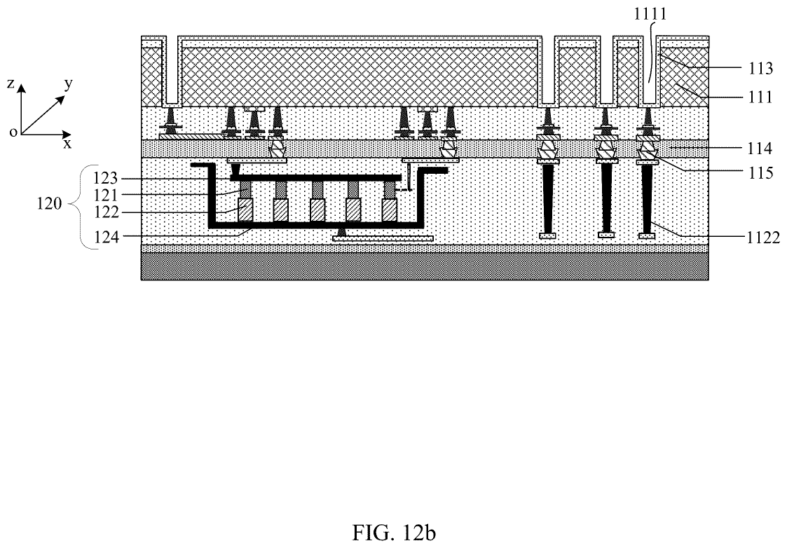

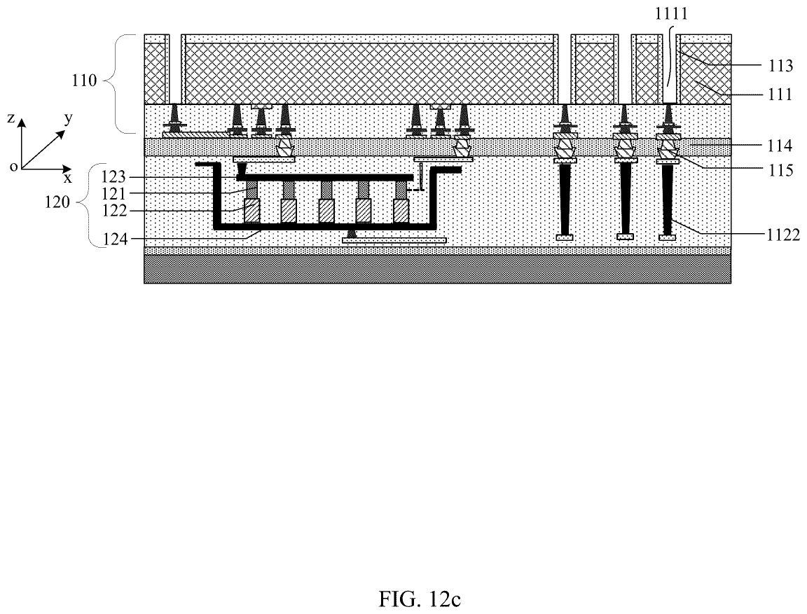

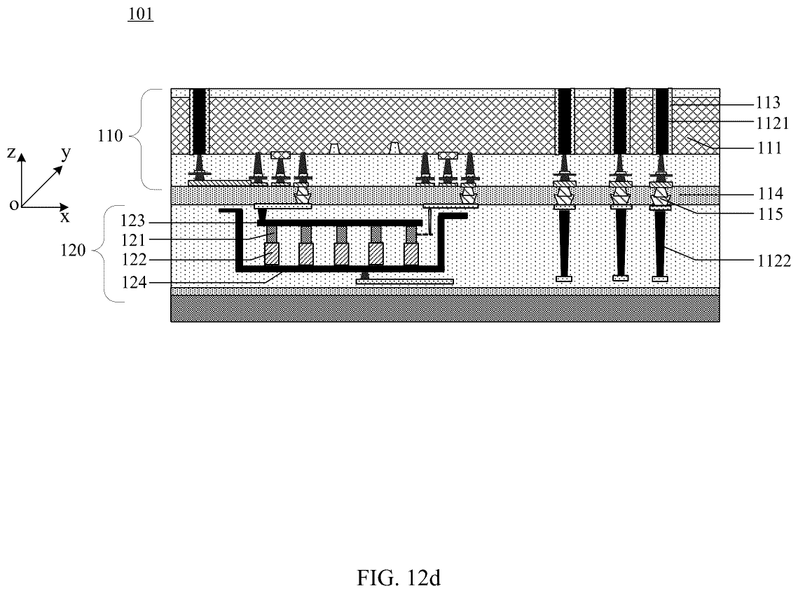

According to some aspects of examples of the present disclosure, a fabrication method of the semiconductor structure 101 in FIG. 1 is provided. In an example, with reference to FIG. 12a, a first semiconductor sub-structure 110 is bonded on a second semiconductor sub-structure 120; a first semiconductor layer 111 of the first semiconductor sub-structure 110 is etched to form an opening 1111 extending through the first semiconductor layer 111, and the opening 1111 may also extend through a dielectric material layer on the first semiconductor layer 111. The dielectric material layer reduces oxidation of the first semiconductor layer 111 and provides electrical insulation.

Before bonding, two bonding layers on a surface to be bonded of the first semiconductor sub-structure 110 and the second semiconductor sub-structure 120 respectively are bonded to form the dielectric layer 114. The bonding layers may not have a physical boundary after the bonding. The dielectric layer 114 may be considered as a bonding layer or a bonding interface formed after bonding two film layers. A contact to be bonded of the first semiconductor sub-structure 110 and a contact to be bonded of the second semiconductor sub-structure 120 may not have a physical boundary after the bonding, and may be considered as a bonding contact 115 in FIG. 12a. The bonding contact 115 extends through the bonding interface and the dielectric layer 114. The first semiconductor sub-structure 110 and the second semiconductor sub-structure 120 may achieve electrical signal interconnection through a first connection sub-structure 1121 and the bonding contact 115. The second semiconductor sub-structure 120 may include a second connection sub-structure 1122 extending along the z-direction, and the second connection sub-structure 1122 may be coupled with the first connection sub-structure 1121 through the bonding contact 115.

With reference to FIG. 12b, an insulation material is deposited on an inner wall of the opening 1111 to form an isolation layer 113. With reference to FIG. 12c, the isolation layer 113 at bottom of the opening 1111 is removed by etching to expose the connection structure under the bottom of the opening 1111, and the connection structure is coupled with the bonding contact 115. With reference to FIG. 12d, a conductive material is filled in FIG. 12d to form the first connection sub-structure 1121. Alternatively, the bonding contact 115 is exposed at the bottom of the opening 1111 of FIG. 12c, and the first connection sub-structure 1121 formed in FIG. 12d is in contact and coupled with the bonding contact 115 directly. When the size of the first semiconductor layer 111 in the z-direction is large, the etched opening has a large aspect ratio; and the size of an open end of the opening 1111 in the x-direction and/or the y-direction may be greater than or equal to the size of the bottom of the opening 1111.

In an example, the etching process may include, but is not limited to, dry etching, wet etching or a combination thereof. The deposition process may include, but is not limited to, chemical vapor deposition (CVD), physical vapor deposition (PVD) and atomic layer deposition (ALD).

In some examples, the first semiconductor sub-structure 110 is bonded with the second semiconductor sub-structure 120 after the first connection sub-structure 1121 is formed in the first semiconductor sub-structure 110.

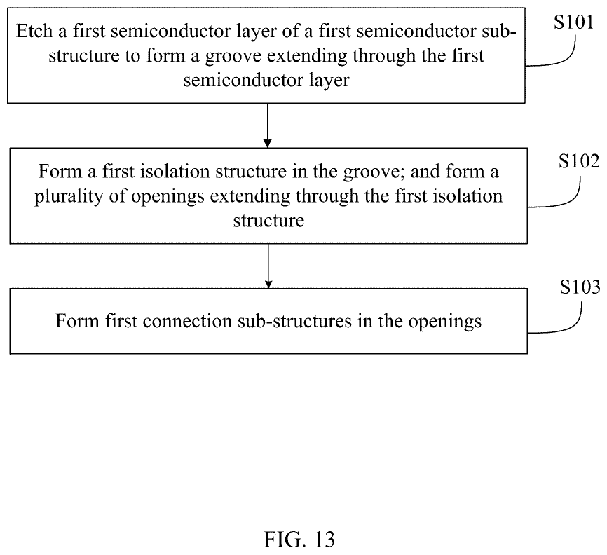

According to some aspects of examples of the present disclosure, FIG. 13 provides a fabrication method of a semiconductor structure 101. The fabrication method includes: etching a first semiconductor layer of a first semiconductor sub-structure to form a groove extending through the first semiconductor layer; forming a first isolation structure in the groove; forming a plurality of openings extending through the first isolation structure; and forming a first connection sub-structure in the opening.

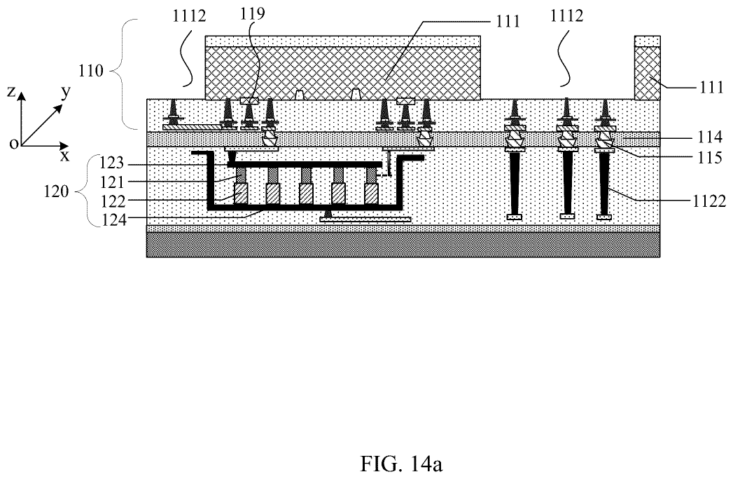

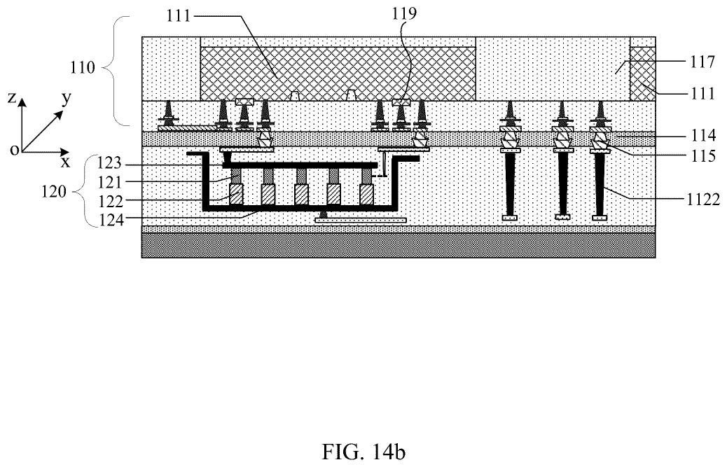

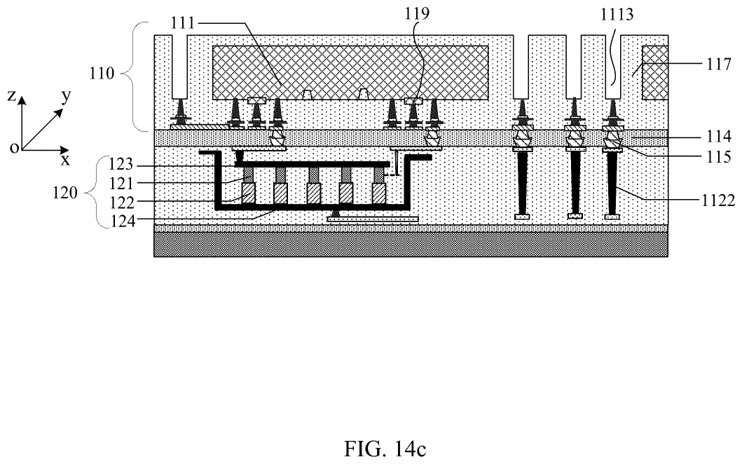

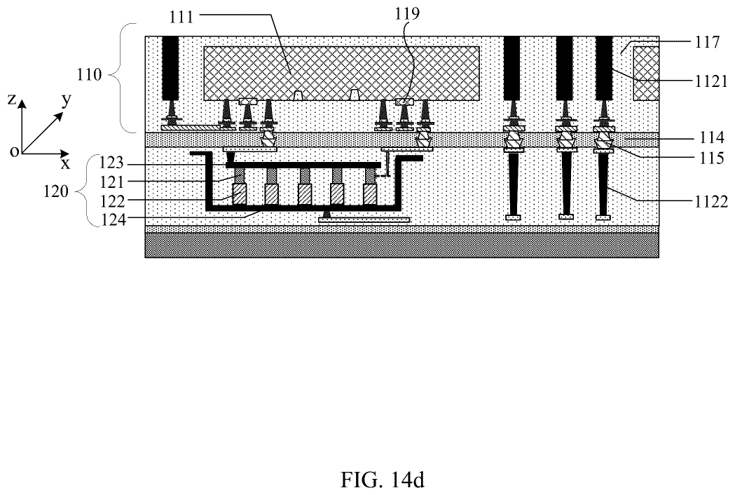

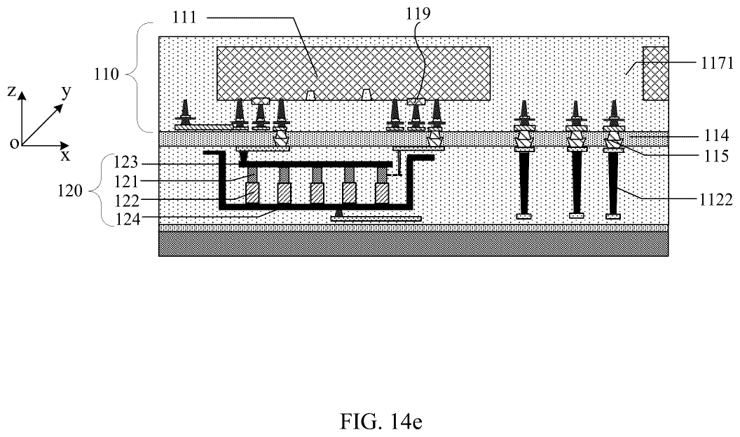

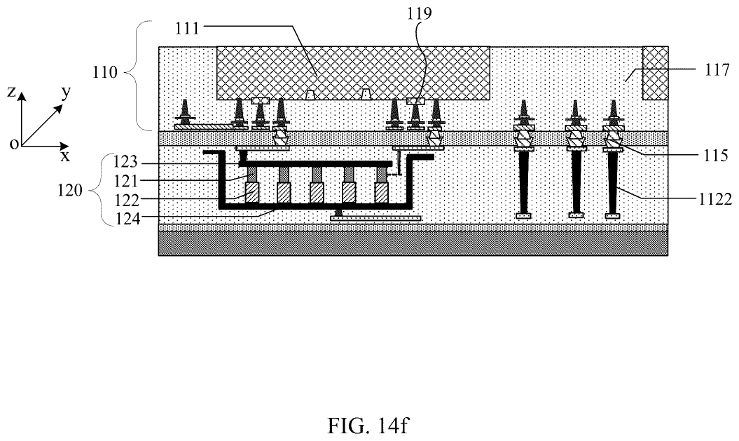

In an example, with reference to FIG. 14a, a first semiconductor sub-structure 110 is bonded on a second semiconductor sub-structure 120; a first semiconductor layer 111 of the first semiconductor sub-structure 110 is etched to form a groove 1112 extending through the first semiconductor layer 111, and the groove 1112 may extend through a dielectric material layer covering the first semiconductor layer 111. With reference to FIG. 14b, the groove 1112 is filled with a dielectric (insulation) material to form a first isolation structure 117. A composition material of the first isolation structure 117 may be the same as the dielectric material layer covering the first semiconductor layer 111. The first isolation structure 117 has no physical boundary with the dielectric material layer, and the first isolation structure 117 may have no physical boundary with the dielectric material under the first semiconductor layer 111. With reference to FIG. 14c, an opening 1113 extending through the first isolation structure 117 is formed, the bottom of the opening 1113 exposes the connection structure or a bonding contact 115 under the first semiconductor layer 111. With reference to FIG. 14d, the opening 1113 is filled with a conductive material to form a first connection sub-structure 1121 that is coupled with the bonding contact 115 through other connection structures, or is in contact and coupled with the bonding contact 115 directly. The size of an open end of the opening 1113 in the x-direction and/or the y-direction may be greater than or equal to the size of the bottom of the opening 1113.

In an example, the groove 1112 in FIG. 14a may continue extending downward after extending through the first semiconductor layer 111, and the bottom of the groove 1112 may or may not expose a connection structure or a conductive plug coupled with the bonding contact 115. Subsequently, the first isolation structure 117 is formed in the groove 1112, and the opening 1113 extending through the first isolation structure 117 exposes the connection structure or the conductive plug coupled with the bonding contact 115, or the opening 1113 exposes the bonding contact 115.

In some examples, the first semiconductor sub-structure 110 includes a device structure on the first semiconductor layer 111; and the fabrication method includes: etching a side of the first semiconductor layer 111 away from the device structure to form the groove 1112. The groove 1112 exposes at least part of the device structure, and the first connection sub-structure 1121 is coupled with at least part of the device structure. The first semiconductor layer 111 may be a semiconductor substrate, and the device structure such as the peripheral circuit, etc. is located on a front side of the first semiconductor layer 111. The peripheral circuit may include, but is not limited to, a CMOS structure 119. The backside of the first semiconductor layer 111 may be thinned, and the thinning process may include etching, wheel grinding and chemical mechanical polishing. The backside of the first semiconductor layer 111 is etched to form the groove 1112 extending through the first semiconductor layer 111. The groove 1112 may expose at least part of the device structure, for example, may expose a conductive plug or an interconnection layer coupled with the bonding contact 115. The first isolation structure 117 is formed in the groove 1112, and the first connection sub-structure 1121 extending through the first isolation structure 117 is formed. At least part of the device structure is coupled with the first connection sub-structure 1121, and at least part of the device structure is coupled with the bonding contact 115.

In some examples, the opening extends along the z-direction. When the opening 1113 has a large aspect ratio, due to a loading effect of the etching, the size of the open end of the opening 1113 in the x-direction is greater than or equal to the size of the bottom of the opening 1113 in the x-direction, where the x-direction intersects the z-direction.

In some examples, with reference to FIG. 4, the fabrication method further includes: forming a pad 116 on the first connection sub-structure 1121. The pad 116 is located on a side of the first semiconductor layer 111 away from the device structure, and the pad 116 is coupled with the first connection sub-structure 1121. The pad 116 is disposed on a side of the first connection sub-structure 1121 away from the bonding contact 115, and may serve as a bonding pad to be coupled with other semiconductor structures 101, or serve as an IO interface for power supply or data transmission.

In some examples, forming the first isolation structure 117 includes: with reference to FIG. 14c, filling a dielectric material 1171 in the groove 1112, where the dielectric material 1171 may cover the first semiconductor layer 111; and with reference to FIG. 14f, planarizing an exposed surface of the dielectric material 1171 to form the first isolation structure 117, where a surface of the first isolation structure 117 is flush with a surface of the first semiconductor layer 111.

In some examples, the fabrication method includes: bonding the first semiconductor sub-structure 110 and the second semiconductor sub-structure 120. The first connection sub-structure 1121 is coupled with the bonding contact 115. The first semiconductor sub-structure 110 includes a peripheral circuit. The second semiconductor sub-structure 120 includes a transistor 121 and a capacitor structure 122 coupled with the transistor 121. The first semiconductor sub-structure 110 is coupled with the second semiconductor sub-structure 120 through the bonding contact 115 and the first connection sub-structure 1121.

In some examples, the fabrication method includes: forming a second connection sub-structure 1122 in the second semiconductor sub-structure 120, where the second connection sub-structure 1122 is coupled with the bonding contact 115.

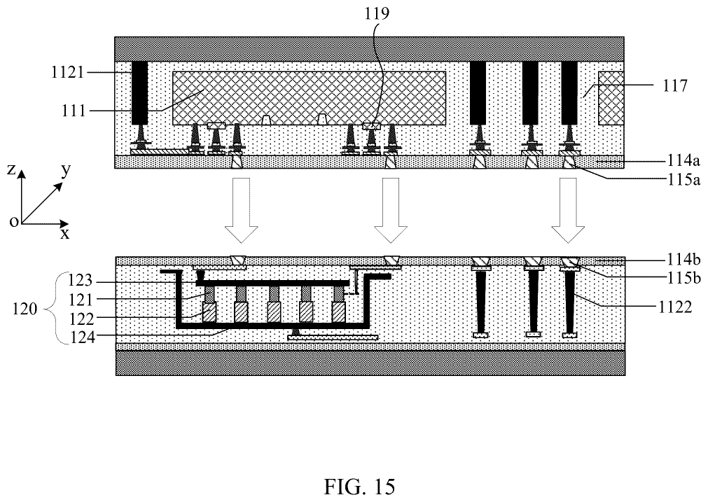

With reference to FIG. 15, firstly, the first isolation structure 117 extending through the first semiconductor layer 111 and the first connection sub-structure 1121 extending through the first isolation structure 117 may be formed in the first semiconductor sub-structure 110, and a first dielectric sub-layer 114a and a first bonding sub-contact 115a extending through the first dielectric sub-layer 114a are formed on a side of the first semiconductor sub-structure 110 having the peripheral circuit, and the first bonding sub-contact 115a is coupled with the peripheral circuit and the first connection sub-structure 1121. The second semiconductor sub-structure 120 is provided and has the second connection sub-structure 1122 extending along the z-direction. A second dielectric sub-layer 114b and a second bonding sub-contact 115b extending through the second dielectric sub-layer 114b are formed on a side of a transistor 121 in the second semiconductor sub-structure 120 away from a capacitor structure 122. Some of the second bonding sub-contacts 115b are coupled with the second connection sub-structure 1122, some of the second bonding sub-contacts 115b are coupled with a gate layer 1212 of the transistor 121, and some of the second bonding sub-contacts 115b are coupled with a bit line 123 that is coupled with the transistor 121. The first semiconductor sub-structure 110 is fixed by means of a carrier wafer, and is bonded with the second semiconductor sub-structure 120. The first dielectric sub-layer 114a and the second dielectric sub-layer 114b are bonded to form the dielectric layer 114 as shown in FIG. 14a. The first bonding sub-contact 115a and the second bonding sub-contact 115b are coupled after the bonding of the dielectric layer 114, and the first bonding sub-contact 115a and the second bonding sub-contact 115b may have no physical boundary after the bonding, such as the bonding contact 115 shown in FIG. 14a.

In some examples, a composition material of the first dielectric sub-layer 114a and the second dielectric sub-layer 114b as a bonding layer or a bonding interface may include, but is not limited to, silicon oxide, silicon nitride, silicon oxynitride, carbon-doped silicon nitride and other insulation materials. The dielectric sub-layer provides electrical isolation for the plurality of bonding contacts 115. The dielectric sub-layer provides a larger bonding area to provide a larger bonding force. The carbon-doped silicon nitride provides a smoother bonding plane and greater bonding strength. A process of doping a carbon element in a silicon nitride thin film may include, but is not limited to, introducing a carbon source gas into the process gas of depositing silicon nitride for in-situ doping of the carbon element, or doping the carbon element for a silicon nitride film layer using a diffusion or ion implantation process. For example, a formation method of the first dielectric sub-layer 114a may include: depositing a silicon nitride thin film doped with the carbon element by using the process gas containing the carbon source gas; or doping the silicon nitride thin film with the carbon element after forming the silicon nitride thin film.

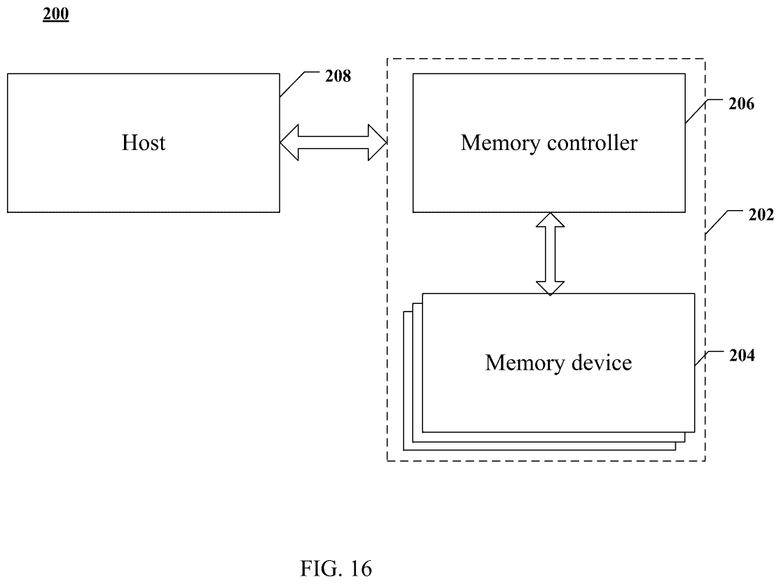

According to some aspects of examples of the present disclosure, FIG. 16 provides a memory system 202 including the semiconductor structure 101 of FIGS. 1, 4 and 5, and the semiconductor structure 10 as shown in FIGS. 9 to 11, and a memory controller 206 coupled with and controlling the semiconductor structures.

With reference to FIG. 16, examples of the present disclosure provide a system 200 including a host 208. The system 200 may be a mobile phone, a graphic processing apparatus, a desktop computer, a laptop computer, a tablet computer, a vehicle computer, a gaming console, a printer, a positioning apparatus, a wearable electronic apparatus, a smart sensor, a virtual reality (VR) apparatus, an augmented reality (AR) apparatus, or any other suitable electronic apparatuses having memories therein. As shown in FIG. 16, the system 200 may include a host 208 and a memory system 202, and the memory system 202 has one or more memory devices 204 and a memory controller 206. The host 208 may be a processor (e.g., a central processing unit (CPU)) or a system on chip (SOC) (e.g., an application processor (AP)) of an electronic apparatus. The host 208 may be configured to send or receive data to or from the memory device 204.

According to some examples, the memory controller 206 is coupled to the memory device 204 and the host 208, and is configured to control the memory device 204 to perform read, write or refresh operation. The memory controller 206 can manage data stored in the memory device 204 and communicate with the host 208. The memory device 204 includes a DRAM, or a package structure formed by stacking a plurality of DRAMs, and may be applied to an HBC or HMC package structure.

In some examples, the HBM package structure may include a plurality of DRAM chips vertically stacked on a logic chip, and the logic chip and the plurality of DRAM chips achieve electrical signal interconnection through TSVs. The plurality of DRAM chips and the logic chip may serve as a memory system. The logic chip may include, but is not limited to, a control logic, an interface control module, an SRAM cache, and other assemblies. The HBM package structure may further include a GPU, a CPU or an SOC and other processor chips. A memory controller may be integrated in the processor to control data transmission of the DRAM chip. In an example, the processor such as the GPU, etc. is coupled with the logic chip, and performs data interaction with the DRAM through the logic chip. In some other examples, the HMC (Hybrid Memory Cube) package structure may include a plurality of DRAM chips vertically stacked on a logic chip, and the logic chip and the plurality of DRAM chips achieve electrical signal interconnection through TSVs. The plurality of DRAM chips and the logic chip may serve as a memory system. The logic chip may include, but is not limited to, a control logic, an interface control module, an SRAM cache, and other assemblies. The logic chip may be integrated with a memory controller.

In some other examples, the memory system 202 is applied to a HBM package product, and may include the semiconductor structure as shown in FIGS. 9 to 11. For example, the third semiconductor chip 13 (the logic chip) may be configured as the memory controller 206. A stack structure of the first semiconductor chip 11 and the second semiconductor chip 12 or more semiconductor chips may be configured as the memory device 204, or the first semiconductor chip 11 and the second semiconductor chip 12 may be configured as the memory devices 204 respectively. The memory system 202 may serve as a memory of the host 208 in the system 200 or a buffer of the system 200.

In some examples, the memory system 202 may be used as an auxiliary device in a solid-state drive, which can make improvements in terms of read and write, etc. of the solid-state drive. Current high-end solid-state drive products mostly select embedded DRAMs to improve the performance of products and improve the random read-write speeds. In an example, when writing a file, especially writing a small file, the small file is stored in a flash after being processed by the DRAMs, such that the solid-state drive has higher storage efficiency and faster speed. The flash includes a non-volatile memory, including, but not limited to, a 2D NAND memory or a 3D NAND memory. In some examples, the memory system 202 may be used as a buffer of a graphic processing unit (GPU) in a graphic processing apparatus which may include, but is not limited to, a graphic card.

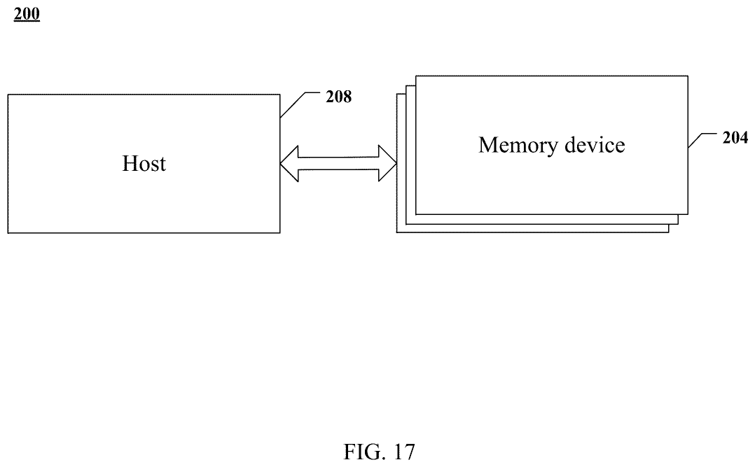

In some other examples, with reference to FIG. 17, the system 200 may include only the host 208 and the memory device 204 coupled with the host 208. A controller that controls the memory device 204 may be located inside the host 208, for example, may be a memory controller integrated in a central processing unit (CPU), or a south bridge or north bridge chip integrated in a mainboard of the system 200. The memory device 204 may include, but is not limited to, a double-data-rate synchronous dynamic random access memory of the DDR4 memory specification or DDR5 memory specification, and a low-power double-data-rate synchronous dynamic random access memory with the LPDDR5 memory specification. The memory device 204 may include the semiconductor structure 101 shown in FIGS. 1, 4 and 5.

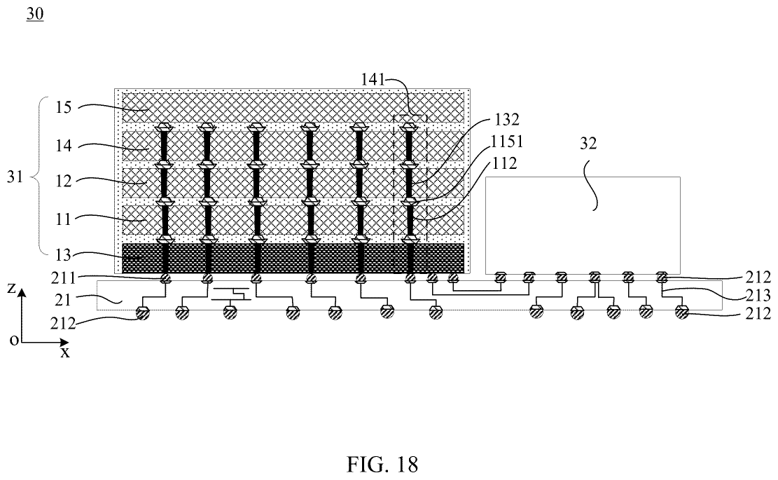

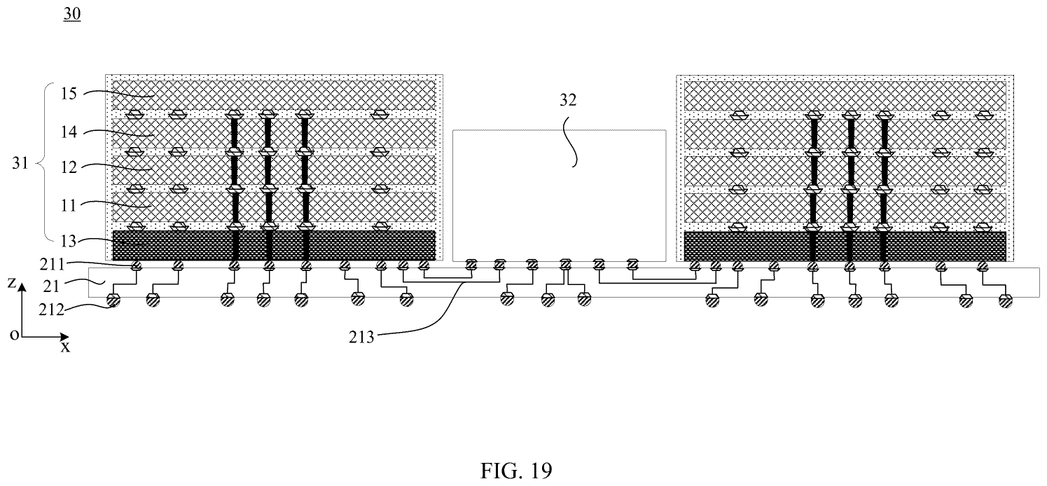

In some examples, FIGS. 18 and 19 illustrate a schematic diagram of a package structure 30. The package structure 30 may be applied to an HBM product, and may serve as an electronic apparatus or part of an electronic apparatus. With reference to FIG. 18, the package structure 30 may include an intermediary substrate 21, a logic chip (which may include the third semiconductor chip 13) on the intermediary substrate 21, a plurality of semiconductor chips stacked on the logic chip along the z-direction, and a processor chip 32 on a horizontal side of the third semiconductor chip 13. The plurality of semiconductor chips may include the first semiconductor chip 11, the second semiconductor chip 12, the fourth semiconductor chip 14 and the fifth semiconductor chip 15 shown in FIG. 11. The plurality of semiconductor chips may be DRAM chips. The semiconductor chips may achieve electrical signal interconnection between each other through a conductive channel 141 extending along the z-direction. The conductive channel 141 may include connection structures located in each semiconductor chip respectively, and bonding contacts or pad couplings between adjacent ones of the electrical connection structures. For example, the first connection structure 112 of the first semiconductor chip 11 is bonded and coupled with the second connection structure 132 of the second semiconductor chip 12 through the first bonding contact 1151, and the first connection structure 112 may be coupled with a third connection structure of the third semiconductor chip 13 through bonding contacts therebetween.

The third semiconductor chip 13 is coupled with the intermediary substrate 21 through a first bump 211 or through hybrid bonding, and the conductive channel 141 is coupled with the first bump 211. The processor chip 32 may be coupled with the intermediary substrate 21 through the first bump 211. The third semiconductor chip 13 may be coupled with the processor chip 32 through the first bump 211 and a routing layer 213 of the intermediary substrate 21, and the routing layer 213 may be located on the intermediary substrate 21 and/or in the intermediary substrate 21. The routing layer 213 may include, but is not limited to, a redistribution layer composed of wirings and contact plugs, which may include a plurality of interconnection layers that are stacked and coupled. The package structure 30 further includes a second bump 212 on a side of the intermediary substrate 21 away from the semiconductor chip, and the second bump 212 may be configured to be coupled with a PCB board to connect the package structure 30 into the integrated circuit. The first bump 211 may be coupled with the second bump 212 through the routing layer 213 in the intermediary substrate 21. In an example, the first bump 211 and the second bump 212 may include, but are not limited to, a solder ball, and a conductive ball.

In some examples, the third semiconductor chip 13 and a plurality of semiconductor chip stacks may constitute a package sub-structure 31 that achieves electrical signal interconnection with the processor chips 32 through the intermediary substrate 21. The package sub-structure 31 may be configured as the memory system 202. The third semiconductor chip 13 may be configured as the memory controller 206 which has a control logic, an interface control module, an SRAM cache and other assemblies. Alternatively, the package sub-structure 31 may be configured as the memory device 204, and the memory controller 206 or at least a control unit of the memory controller 206 is integrated in the processor chip 32, for example, an HBM controller or a memory controller is integrated in the processor chip 32.

In some examples, with reference to FIG. 19, one processor chip 32 and a plurality of package sub-structures 31 may be integrated on the intermediary substrate 21 to constitute the package structure 30. Each package sub-structure 31 and the processor chip 32 may achieve electrical signal interconnection through the first bump 211 and the intermediary substrate 21.

In some examples, the package structure 30 further includes a molded layer covering the package sub-structure 31, the processor chip 32 and the intermediary substrate 21 to protect devices. The molded layer may include, but is not limited to, silicon oxide, epoxy resin, polyurethane and other insulation materials. The outer surface of the molded layer may be cladded with a conductive layer to shield electromagnetic interference and dissipate heat, and a heat dissipation lid or a heat sink may be disposed above the package sub-structure 31 and the processor chip 32 to facilitate heat dissipation.

In some examples provided by the present disclosure, it is to be understood that the disclosed apparatus and method may be implemented in a non-objective manner. The apparatus examples described above are only illustrative, for example, the division of units is merely a division of logical functions. In actual implementations, there may be other division methods. For instance, a plurality of units or assemblies may be combined, or may be integrated to another system, or some features may be omitted or not performed. In addition, the various components as shown or as discussed may be coupled directly or indirectly. The methods disclosed in several method examples provided by the present disclosure may be combined arbitrarily in case of no conflicts, so as to obtain a new method example.

The above descriptions are merely specific implementations of the present disclosure, and the protection scope of the present disclosure is not limited thereto. Any variation or replacement that may be readily figured out by those skilled in the art within the technical scope disclosed by the present disclosure shall fall within the protection scope of the present disclosure.

What is claimed is:

1. A semiconductor structure, comprising:
a first semiconductor chip and a second semiconductor chip that are bonded along a first direction, wherein the first semiconductor chip comprises:
a first semiconductor layer; and
a plurality of first connection structures extending through the first semiconductor layer along the first direction, wherein a dielectric material is between and in contact with any two of the first connection structures, and wherein
the first semiconductor chip and the second semiconductor chip are coupled by a plurality of first bonding contacts and the plurality of first connection structures, wherein the plurality of first bonding contacts extend through a first dielectric layer, and the first connection structure is coupled with the first bonding contact.

2. The semiconductor structure of claim 1, wherein the first semiconductor chip comprises:
a first isolation structure extending through the first semiconductor layer along the first direction and comprising the dielectric material, wherein the plurality of first connection structures extend through the first isolation structure along the first direction.

3. The semiconductor structure of claim 1, wherein a size in a second direction of an end of the first connection structure close to the second semiconductor chip along the first direction is greater than or equal to a size in the second direction of an end of the first connection structure away from the second semiconductor chip, and wherein the second direction intersects the first direction.

4. The semiconductor structure of claim 1, wherein the first semiconductor chip comprises:
a first semiconductor sub-structure and a second semiconductor sub-structure that are bonded along the first direction, wherein the first semiconductor layer is located in the first semiconductor sub-structure and located between the second semiconductor sub-structure and the second semiconductor chip; and the first semiconductor sub-structure and the second semiconductor sub-structure are coupled by a plurality of second bonding contacts extending through a second dielectric layer; and wherein
the first connection structure comprises a first connection sub-structure in the first semiconductor sub-structure and a second connection sub-structure in the second semiconductor sub-structure, wherein the second bonding contacts are located between the first connection sub-structure and the second connection sub-structure; and wherein the first connection sub-structure and the second connection sub-structure are coupled by the second bonding contacts.

5. The semiconductor structure of claim 1, wherein the second semiconductor chip comprises:
a third semiconductor sub-structure and a fourth semiconductor sub-structure that are bonded in the first direction,
wherein the fourth semiconductor sub-structure is located between the first semiconductor chip and the third semiconductor sub-structure,
wherein the fourth semiconductor sub-structure and the third semiconductor sub-structure are coupled by a plurality of third bonding contacts extending through a third dielectric layer, and
wherein the third dielectric layer and the first dielectric layer are located on two sides of the fourth semiconductor sub-structure that are opposite in the first direction.

6. The semiconductor structure of claim 5, wherein the second semiconductor chip further comprises:
a second connection structure extending along the first direction, wherein the second connection structure is located between the first bonding contact and the third bonding contact, and wherein the second connection structure is coupled with the first bonding contact and the third bonding contact.

7. The semiconductor structure of claim 6, wherein the second connection structure comprises:
a third connection sub-structure in the third semiconductor sub-structure and a fourth connection sub-structure in the fourth semiconductor sub-structure, wherein the third bonding contact is located between the third connection sub-structure and the fourth connection sub-structure, and wherein the third connection sub-structure and the fourth connection sub-structure are coupled by the third bonding contact.

8. The semiconductor structure of claim 7, wherein the third semiconductor sub-structure further comprises:
a second semiconductor layer and a second isolation structure extending through the second semiconductor layer along the first direction, wherein a plurality of the third connection sub-structures extend through the second isolation structure.

9. The semiconductor structure of claim 4, wherein the second semiconductor sub-structure comprises:
a transistor comprising a first active region, a second active region, and a gate layer;
a bit line coupled with the first active region; and
a capacitor structure coupled with the second active region.

10. The semiconductor structure of claim 9, wherein the transistor comprises:
a semiconductor pillar extending along the first direction, wherein the first active region and the second active region are located at two ends of the semiconductor pillar that are opposite in the first direction,
wherein the gate layer extends along a direction intersecting the first direction, and wherein the gate layer covers part of a side of the semiconductor pillar.

11. The semiconductor structure of claim 9, wherein the first semiconductor sub-structure comprises:
a peripheral circuit coupled with the bit line by part of the second bonding contacts and coupled with the gate layer by another part of the second bonding contacts.

12. The semiconductor structure of claim 1, further comprising:
a third semiconductor chip located on a side of the first semiconductor chip away from the second semiconductor chip; and
an intermediary substrate located on a side of the third semiconductor chip away from the first semiconductor chip, wherein the third semiconductor chip is coupled with the intermediary substrate;
wherein the third semiconductor chip comprises a control logic circuit and is bonded with the first semiconductor chip, and the first connection structure is coupled with the third semiconductor chip.

13. A semiconductor structure, comprising:
a first semiconductor sub-structure and a second semiconductor sub-structure that are bonded in a first direction, wherein the first semiconductor sub-structure comprises:
a first semiconductor layer; and
a plurality of first connection sub-structures extending through the first semiconductor layer along the first direction, wherein a dielectric material is between and in contact with any two of the first connection sub-structures; and wherein
the semiconductor structure further comprises a pad that is located on a side of the first semiconductor sub-structure away from the second semiconductor sub-structure and is coupled with the first connection sub-structure.

14. A method of fabricating a semiconductor structure, comprising:
etching a first semiconductor layer of a first semiconductor sub-structure to form a groove extending through the first semiconductor layer;
filling a dielectric material in the groove to form a first isolation structure;
forming a plurality of openings extending through the first isolation structure; and
forming first connection sub-structures in the openings.

15. The method of claim 14, wherein the first semiconductor sub-structure comprises a device structure on the first semiconductor layer, and wherein the method further comprises:
etching a side of the first semiconductor layer away from the device structure to form the groove, wherein the groove exposes at least part of the device structure, and the first connection sub-structure is coupled with at least part of the device structure.

16. The method of claim 14, wherein the openings extend along a first direction, and a size of an open end of the opening in a second direction is greater than or equal to a size of a bottom of the opening in the second direction, and wherein the second direction intersects the first direction.

17. The method of claim 15, further comprising:
forming a pad on the first connection sub-structure, wherein the pad is located on a side of the first semiconductor layer away from the device structure and is coupled with the first connection sub-structure.

18. The method of claim 14, wherein the forming the first isolation structure comprises:
filling a dielectric material in the groove; and
planarizing an exposed surface of the dielectric material to form the first isolation structure, wherein a surface of the first isolation structure is flush with a surface of the first semiconductor layer.

19. The method of claim 15, comprising:
bonding the first semiconductor sub-structure with a second semiconductor sub-structure, wherein the first connection sub-structure is coupled with a bonding contact,
wherein the first semiconductor sub-structure comprises a peripheral circuit,
wherein the second semiconductor sub-structure comprises a transistor and a capacitor structure coupled with the transistor, and
wherein the first semiconductor sub-structure and the second semiconductor sub-structure are coupled by the bonding contact and the first connection sub-structure.

20. The method of claim 19, comprising:
forming a second connection sub-structure in the second semiconductor sub-structure, wherein the second connection sub-structure is coupled with the bonding contact.
